(19) United States
(12) Patent Application Publication
(10) Pub. No.: US 2008/0237657 A1
(43) Pub. Date: Oct. 2, 2008

(54) Signaling circuit and method for integrated circuit devices and systems

(75) Inventor: Ashok K. Kapoor, Palo Alto, CA (US)

Correspondence Address: HAVERSTOCK & OWENS, LLP, 162 North Wolfe Road, Sunnyvale, CA, 94086, US

(73) Assignee: DSM Solution, Inc.

(21) Appl. No.: 12/072,009

(22) Filed: Feb. 21, 2008

Related U.S. Application Data
(63) Continuation-in-part of application No. 11/728,463, filed on Mar. 26, 2007.

(51) Int. Cl. H01L 27/06; H01L 27/12; H01L 21/8248

(52) U.S. Cl. 257/273; 438/189; 257/E27.015; 257/E21.695; 257/E27.112

(57) ABSTRACT

An integrated circuit device can include at least one bipolar junction transistor (BJT) having a first base electrode comprising a semiconductor material doped to a first conductivity type formed on and in contact with a surface of the semiconductor substrate, and separated from an emitter electrode by a separation space. A first base region can be formed in the substrate below the emitter electrode and include a first portion of the substrate doped to the first conductivity type. A second base region can be formed in the substrate below the separation space and can include a second portion of the substrate doped to the first conductivity type.

This application is a continuation-in-part of U.S. patent application Ser. No. 11/728,463, filed on Mar. 26, 2007.

### TECHNICAL FIELD

The present invention relates generally to semiconductor integrated circuit devices, and more particularly to circuits and methods for transmitting, receiving and distributing signals on an integrated circuit and systems including integrated circuits.

### BACKGROUND OF THE INVENTION

Integrated circuit (IC) devices typically include a number of sections formed in one or more substrates that are electrically interconnected to one another. As operating speeds for such devices has increased, the transmission of electrical signals across ICs with predetermined timing has become source of many design concerns, including timing failures and power consumption. Timing failures can arise due to instability of power supply levels, including “voltage droop” (a drop in a high power supply level) and/or “ground bounce” (a rise in a low power supply level). Timing failures can also arise due to transmission line effects, which can generate reflections at a signal receiving end that can propagate back to a signal source.

Power consumption is an increasing concern due to the switching of signals, particularly periodic signals, such as clock signals. Lines carrying such signals are typically driven between power supply levels in conventional approaches. As operating speeds of integrated circuits have increased, so have the switching rate of such signals. As a result, timing signals, particularly clock signals, can now account for a significant portion of overall power consumption.

To better understand various features of the disclosed embodiments, a number of conventional signaling approaches will now be described.

Referring now to FIGS. 15A and 15B, a conventional IC signaling example is shown in a block schematic diagram and a timing diagram. FIG. 15A shows two signaling paths subject to unwanted crosstalk. Crosstalk can occur when signals are unintentionally coupled to one another, via a mutual capacitance between two signal lines. FIG. 15A shows a first signaling path 1500 for a clock signal CLK, and a second signaling path 1502 for a signal S1. A signal CLK can be a periodic signal that can be distributed over an integrated circuit device to ensure that operations are executed according to a predetermined timing. As such, a clock signal CLK can be active while an integrated circuit is in a normal operating mode. A signal S1 can be a signal generated during the operation of the integrated circuit. The rate at which signal S1 switches with respect to signal CLK can be much slower.

Each conventional signal path (1500 and 1502) can include a number of signal buffers 1504 interconnected by signal lines 1506 and 1508. Signal path 1500 receives signal CLK and outputs clock signal CLK_OUT. Signal path 1502 receives signal S1_IN and output signal S1_OUT.

FIG. 15B is a timing diagram showing waveforms corresponding to the two signaling paths of FIG. 15A. Waveform CLK can be clock signal CLK transmitted by signal path 1500. Waveform S1_START can be an initial output signal on signal path 1502. Waveform S1_END can be a signal from signal path 1502 at the end of signal line 1508. As shown, due to capacitive coupling, a signal line 1508 can rise or fall in synchronism with transitions in the clock signal CLK, rather than maintain one particular state (high or low). Absent the effects of a crosstalk, a signal S1_END can transition as desired (shown as “no xtalk”). However, due to crosstalk signal S1_END can have an unwanted delay (shown as “xtalk”), as a driver compensates for a dip in the power supply level.

In this way, capacitive coupling can result in unwanted signal delay. While capacitive coupling of signals, particularly periodic signals, can adversely impact signal transmission, such effects can also impact power supply stability. This is shown in the conventional example of FIGS. 16A to 16C. FIG. 16A shows an integrated circuit 1600 power supply routing. A high power supply voltage VDD can be provided via wiring 1602, while a low power supply voltage GND can be provided via wiring 1604. In this way, power supply voltages (VDD and GND) can be provided to different blocks within integrated circuit 1600. It is understood that operations within integrated circuit 1600 can be timed according to a clock signal CLK.

Referring now to FIG. 16B, a timing diagram shows a relationship between clock signals and power supply voltages for different blocks of integrated circuit 1600. FIG. 16B shows a clock signal CLK. In addition, the waveforms show high power supply voltages for two different blocks VDD(BLK1) and VDD(BLK2), as well as low power supply voltages for such different blocks GND(BLK1) and GND(BLK2). As shown in the figure, because a majority of circuit operations are activated in response to a clock signal (CLK) or its inverse (CLKB, not shown), there can be a droop (temporary drop) in a high power supply voltage level, as well as bounces (temporary rise) in low power supply voltage levels. Such deviations can be in synchronism with clock signal transitions.

Referring now to FIG. 16C, one potential impact resulting from dips in a power supply voltage is shown in a timing diagram. FIG. 16C shows two waveforms, one for a switching response SBLK1 that has been adversely affected by power supply level instability, and another switching response SBLK2 that has been minimally affected by power supply instability. As shown, because a power supply voltages can be lower (or higher) at the time a signal switches state, the resulting switching speed can be slower than an ideal response. In this way, the effects of timing signals on power supply voltage levels can adversely affect the speed at which signals switch between levels.

Referring now to FIG. 17, one very particular example of a conventional IC clock scheme is shown in a top plan view, and designated by the general reference character 1700. An IC can include a number of sections, including “core” sections 1702, (input/output) I/O sections 1704, and a clock section 1706. A clock section 1706 can receive a clock input signal CLK_EXT, and in response thereto, generate an internal clock signal CLK_IN. A clock section 1706 can include various phase shifting circuits, such as delay locked loop (DLL) or phase locked loop (PLL) type circuits, as well as buffer/pulse shaping circuits. Alternatively, a clock section 1706 can generate a clock signal with an oscillator, or the like.

To ensure proper timing, a clock signal CLK_IN can be distributed to each of the core and I/O sections (1702 and 1704). Additional clock branching and buffering can occur within the various sections (1702 and 1704). In such a conventional clock distribution network, buffers can be included to ensure a propagation delay does not exceed a predetermined maximum delay. Clock signal CLK_IN can thus be distributed over an IC 1700 by a network that includes numerous conductive lines having an inherent capacitance. In such an arrangement, as a timing signal is driven on such lines, power consumption can be consumed according to the following relationship:

Power αCₙₑₜV²,

where Cₙₑₜ is the capacitance of the network, and V is the magnitude of the signal swing. Thus, the transmission of such a signal can consume considerable power during the operation of the integrated circuit. Further, the power consumption varies according to the square of the clock signal amplitude.

FIG. 17 shows a conventional integrated circuit that can be of the complementary metal oxide semiconductor (CMOS) type. Further, the example shown, clock circuits are assumed to be CMOS buffer type circuits, and so drive a clock signal between a low power supply voltage (e.g., ground) and a high power supply voltage VDD.

Because operations of the circuit are based on a clock signal CLK_IN, the clock signal typically has the fastest frequency of all timing signal. As a result, a clock distribution can represent a substantial portion of the overall power consumption for the IC 1700.

While the above description of FIG. 17 can include a CMOS type circuit, for additional performance, other conventional IC technologies have been employed. For example, conventional approaches have integrated bipolar transistors with CMOS transistors to form “BiCMOS” integrated circuits. Such circuits typically utilize bipolar junction transistors (BJTs) for faster switching speeds, to provide faster signal driving capabilities, or to provide I/O circuits compatible with bipolar related signaling conventions (e.g., transistor-transistor logic (TTL) or emitter-coupled logic (ECL)).

FIG. 18 is a block schematic diagram representation of a conventional clock distribution arrangement. An IC 1800 can include a clock section 1802, a clock distribution network 1804, and a number of circuit blocks 1806-0 to 1806-5. A clock section 1802 can provide a clock signal CLK to a network 1804. Network 1804 can provide a clock signal to circuit blocks (1806-0 to 1806-5). As shown, clock section 1802 and circuit blocks (1806-0 to 1806-5) can operate between voltage levels VDD and Vgnd. Thus, a clock signal CLK can vary between VDD and Vgnd. It is understood that network 1804 can include buffers and the like also operating between VDD and Vgnd.

Conventional BiCMOS may provide circuits that can still consume considerable power, as they can drive voltages between VDD and V_{BE}, where V_{BE} is the base-emitter bias. Thus, such approaches can consume power according to the relationship: Power αCₙₑₜ(V−V_{BE})², which can still be a considerable power supply draw. In addition, conventional BiCMOS devices have not scaled to the lower power supply voltages included in advanced CMOS devices.

### BRIEF DESCRIPTION OF THE DRAWINGS

FIG. 1A is a block schematic diagram of an integrated circuit device according to one embodiment.

FIG. 1B is a block schematic diagram of a system according to another embodiment.

FIG. 1C is a block schematic diagram of a system according to yet another embodiment.

FIGS. 2A and 2B are block schematic diagrams of signal paths according to two more embodiments.

FIGS. 3A and 3B are schematic diagrams of field effect transistor (FET) buffers that can be included in the embodiments.

FIGS. 4A to 4F are schematic diagrams emitter coupled logic (ECL) type circuits that can be included in the embodiments.

FIG. 5A is a table showing power consumption differences between conventional signal driving arrangements and that according to one embodiment.

FIG. 5B is a timing diagram showing current switching differences between conventional signal driving arrangements and that according to one embodiment.

FIG. 6 is a timing diagram showing one example of signals levels according to an embodiment.

FIGS. 7A to 8C are various views showing a device structure that can be included in the embodiments.

FIG. 9 is a top plan view showing an interconnection of device structures according to one embodiment.

FIG. 10A is a diagram showing a system and method according to an embodiment.

FIG. 10B is a diagram showing a timing model according to one embodiment.

FIG. 11 is a diagram showing another system and method according to an embodiment.

FIG. 12 is a diagram showing a clock tree according to an embodiment.

FIG. 13 is a diagram showing an integrated circuit design according to an embodiment.

FIG. 14 is a timing diagram showing improvements in signal transmission according to an embodiment.

FIG. 15A is a block schematic diagram showing conventional signaling paths.

FIG. 15B is a timing diagram showing the operation of the signaling paths of FIG. 15A.

FIG. 16A is a diagram showing a conventional clock distribution network.

FIG. 16B is a timing diagram showing a relationship between clock signals and a power supply voltage in a conventional arrangement.

FIG. 16C is a timing diagram showing the effect clock signals on slower frequency signals in a conventional arrangement.

FIG. 17 is a top plan view of a conventional integrated circuit (IC) clock scheme.

FIG. 18 a block schematic diagram of a conventional clock distribution arrangement.

FIGS. 19A-0 to 19P show various views of additional device structures that can be included in the embodiments.

FIGS. 20A and 20B show two views of a bipolar junction transistor (BJT) device that can be included in the embodiments.

FIGS. 21A and 21B show two views of a BJT device that can be included in the embodiments.

FIGS. 22A and 22B show two views of a BJT device that can be included in the embodiments.

FIGS. 23A and 23B show two views of a BJT device that can be included in the embodiments.

FIG. 24 is a flow diagram showing the steps described in FIGS. 19A to 19N.

### DETAILED DESCRIPTION OF THE EMBODIMENTS

Various embodiments of the present invention will now be described in detail with reference to a number of drawings. The embodiments show structures, designs, and methods for an integrated circuit (IC) device that can consume less power and/or interfere less with other signals in the same IC device than conventional approaches, like those of complementary metal oxide semiconductor (CMOS) type ICs. Various embodiments can include bipolar transistors formed in the same integrated circuit as other transistors types, preferably in the same substrate as field effect transistors (FETs).

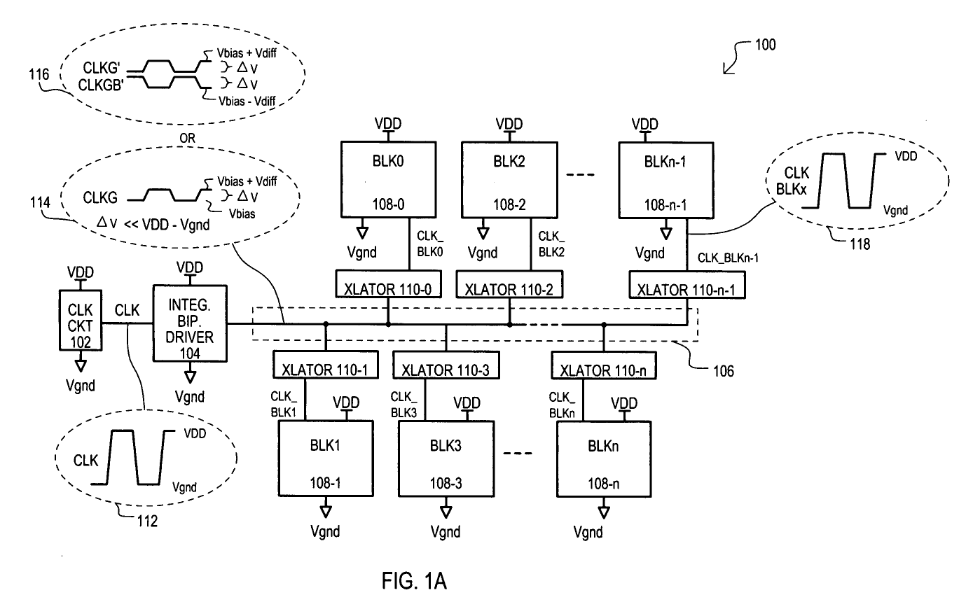

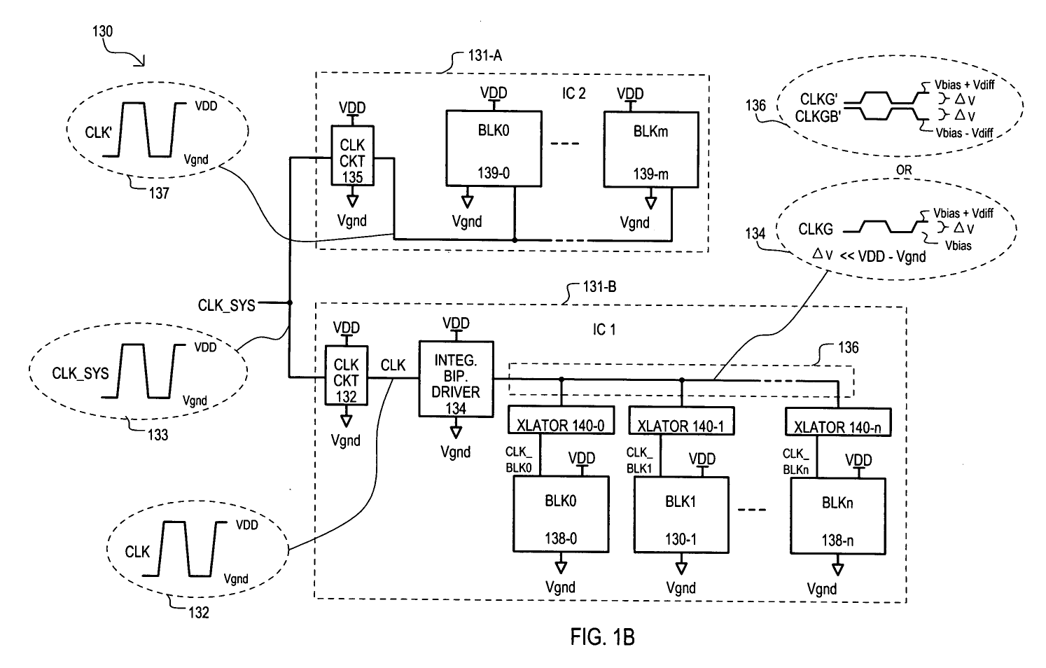

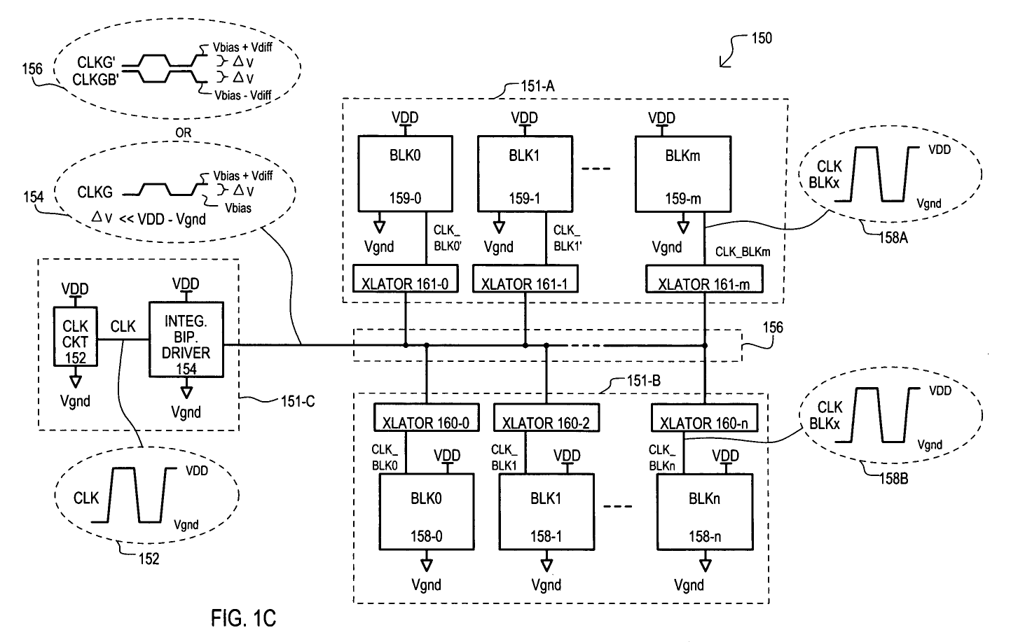

Referring now to FIG. 1A, an IC according to a first embodiment is shown in a block schematic diagram, and designated by the general reference character 100. An IC 100 can include a signal source circuit 102, a global transmitter circuit 104, a global wiring network 106, and a number of circuit blocks 108-0 to 108-n. Each circuit block (108-0 to 108-n) can be connected to global wiring network 106 by corresponding translator circuits 110-0 to 110-n.

A signal source circuit 102 can generate an initial signal CLK. A signal source circuit 102 can operate between a high power supply voltage and a low power supply voltage, in this example, shown as VDD and Vgnd, respectively. Further, in the particular example shown, an initial signal CLK can be a signal having a voltage swing between a high power supply voltage VDD and low power supply voltage Vgnd. This is shown by example in waveform illustration 112.

A signal source circuit 102 can preferably be a clock input circuit that receives a timing signal originating from a source external to the IC 100. In such an arrangement, a signal source circuit 102 can be a buffer circuit. In particular arrangements, such a buffer circuit can include phase adjustment circuits, such a phase lock loop or delay lock loop type circuits, as well as frequency multipliers and/or dividers. However, in alternate embodiments, a timing source circuit 102 can self-generate an initial signal CLK. In such arrangements, a signal source circuit 102 can include an oscillator, as but one example.

Preferably, an initial signal CLK is a periodic signal active during normal operations of IC 100. Further, a signal source circuit 102 can have active circuit elements that can include field effect transistors (FETs), such as junction FETs (JFETs), insulated gate FETs (IGFETs), or some combination thereof.

A global transmitter circuit 104 can receive initial signal CLK, and in response thereto, generate one or more global signals CLKG. Two possible global signaling examples are shown in FIG. 1A: single ended signaling and differential signaling. Signal ended signaling is shown by waveform 114, and can include a signal that varies between a bias voltage Vbias and some offset from the bias voltage. In example shown, the offset is positive (e.g., Vbias+Vdiff). However, in alternate arrangements such an offset can be negative. A difference between global timing signal levels is shown as ΔV. Differential signaling is shown by waveform 116, and can include a first signal that varies between a bias voltage Vbias and a positive offset (e.g., Vbias+Vdiff), and a second signal the varies between bias voltage Vbias and a negative offset (e.g., Vbias−Vdiff).

A global wiring network 106 can include wiring structures for transmitting global signals (i.e., CLKG or CLKG′/CLKGB′) from global transmitter circuit 104 to translator circuits (110-0 to 110-n). For example, in arrangements having single ended signaling, a global wiring network 106 can include single wirings routes while differential signaling can include dual wiring routes. Further, a global wiring network 106 can include one or more repeaters.

Circuit blocks 108-0 to 108-n can be circuits that operate in response to local signals CLK_BLK0 to CLK_BLKn. In example of FIG. 1A, each circuit block (108-0 to 108-n) can operate between a high power supply voltage (VDD) and a low power supply voltage (Vgnd). In addition, each timing signal (CLK_BLK0 to CLK_BLKn) can be a signal having a voltage swing greater than that of a global timing signal (i.e., greater than ΔV). Preferably, local signals (CLK_BLK0 to CLK_BLKn) can vary between high power supply voltage VDD and low power supply voltage Vgnd. This is shown by example in waveform illustration 118.

Preferably, local signals (CLK_BLK0 to CLK_BLKn) can be periodic timing signals active during normal operations of IC 100. Further, any or all of circuit blocks (108-0 to 108-n) can have active circuit elements that include only, or substantially only, JFETs, IGFETs or some combination.

In one very particular arrangement, circuit blocks 108-0 to 108-n can be circuits formed with complementary IGFETs (e.g., CMOS), while a high power supply voltage VDD can be about 1.0 volts, and a low power supply voltage can be about 0 volts. At the same time, a global transmitter circuit 104 can be an ECL type circuit, and ΔV can be about 0.1 V. Such a significant reduction in signal voltage can reduce capacitive coupling effects between a global signal(s) (e.g., CLKG or CLKG′/CLKGB′) and lower frequency signals, such a logic signals generated within a circuit block (108-0 to 108-n).

In another very particular arrangement, circuit blocks 108-0 to 108-n can be circuits formed with complementary JFETs, while a high power supply voltage VDD can be about 0.5 volts, and a low power supply voltage can be about 0 volts. A global transmitter circuit 104 can provide a ΔV of about 0.1 V. This too, can provide a significant reduction in capacitive coupling effects between a global signal (e.g., CLKG or CLKG′/CLKGB′) and lower frequency signals, such a logic signals generated within a circuit block.

Each translator circuit (110-0 to 110-n) can receive a single or differential global timing signal (Vbias+Vdiff and/or Vbias−Vdiff), and in response thereto, generate a local timing signal CLK_BLK0 to CLK_BLKn for a corresponding circuit block (108-0 to 108-n). Local timing signals (CLK_BLK0 to CLK_BLKn) can vary between a high power supply voltage VDD and a low power supply voltage Vgnd.

As will be shown in more detail below, reductions in global signal voltage swing can result in substantial reductions in power consumption as compared to conventional approaches having a signal that swings between power supply voltages (i.e., rail-to-rail).

In this way, an integrated circuit device can have a global signal network that provides a signal to multiple sections having a lower voltage swing than signals within each of such sections.

While embodiments can include inter-chip signaling (signaling within one integrated circuit), alternate embodiments can include systems in which signaling occurs between integrated circuits. Two of the many possible examples of such systems are shown in FIGS. 1B and 1C.

Referring now to FIG. 1B, a system 130 according to one embodiment is shown in a block schematic diagram. A system 130 can include multiple integrated circuits, where one or more integrated circuits have high voltage swing signals, while one or more other integrated circuits have low voltage swing signals.

In the particular example of FIG. 1B, a system 130 can receive or generate a system clock signal CLK_SYS. A system clock signal CLK_SYS can be a signal having a voltage swing between a high power supply voltage VDD and low power supply voltage Vgnd. This is shown by example in waveform illustration 133.

A system 130 can include an integrated circuit 131-A that includes a clock circuit 135 that receives a system clock CLK_SYS and generates an internal clock signal CLK′. Internal clock signal CLK′ can be a signal having a voltage swing between a high power supply voltage VDD and low power supply voltage Vgnd. This is shown by example in waveform illustration 137.

A system 130 can further include an integrated circuit 131-B having the same general structure as that shown in FIG. 1A.

In this way, a system can receive a high swing voltage signal that is provided to an integrated circuit operating at such high swing levels, as well as another integrated circuit operating at lower voltage swing levels.

Referring now to FIG. 1C, a system 150 according to another embodiment is shown in a block schematic diagram. A system 150 can also include multiple integrated circuits. However, in the arrangement of FIG. 1C, a signal transmitted between integrated circuits 151-A and 151-B can be a low voltage swing signal, or signals.

Inter-chip low voltage swing signals (CLKG or CLKG′/CLKGB′) can be generated by a clock section 151-C. A clock section 151-C can be separate from, or be a portion of either of integrated circuits 151-A or 151-B.

In this way, a system can include low voltage swing signals between integrated circuits.

Having described a signaling arrangement for an integrated circuit device, particular signaling arrangements will now be described in more detail.

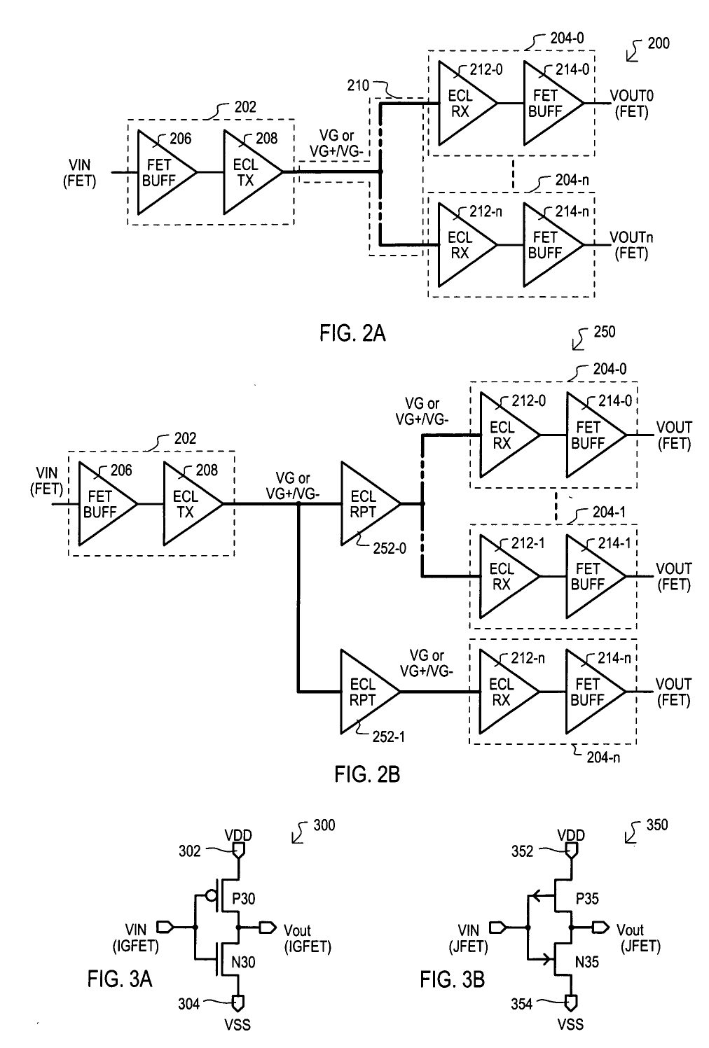

Referring now to FIG. 2A, a signal path according to one embodiment is shown in a block schematic diagram, and designated by the general reference character 200. A signal path 200 can be formed on an integrated circuit can include a global signal transmitter 202 and a number of translator circuits 204-0 to 204-n. A signal transmitter 202 can include a FET buffer 206 and a low voltage (LV) transmission buffer 208. A FET buffer 206 can receive an input signal VIN that can have a FET buffer signal level. For example, a FET buffer 206 can receive a signal that varies between a high and low power supply level, and in response thereto, output a signal that varies at the same level. A LV transmission buffer 208 can receive the output signal from the FET buffer 206, and output a signal VG having a swing that is substantially less than that of VIN. In one example, a swing of signal VG can be no more than ⅕ that of signal VIN. Alternatively, a FET buffer 206 can output a differential signal pair VG+/VG−, each of which can have a swing that is substantially less than that of VIN, and in one example no more than ⅕ that of signal VIN.

Referring still to FIG. 2A, a LV transmission buffer 208 can have an output connected to a global wiring 210. A global wiring 210 can provide a low voltage swing signal VG (or differential signals VG−/VG+), to translator circuits (204-0 to 204-n).

In the particular example of FIG. 2A, each translator circuit (204-0 to 204-n) can include a LV receiver buffer (212-0 to 212-n) and a local FET buffer (214-0 to 214-n). A LV receiver buffer (212-0 to 212-n) can receive a low voltage swing signal VG (or differential signals VG−/VG+), and in response thereto, output a signal at the VIN level. A local FET buffer (214-0 to 214-n) can operate in the same general fashion as FET buffer 206, receiving a large swing signal (with respect to VG/VG−/VG+), and outputting a signal at the same level.

In this way, a signal path can receive an input signal having a large signal swing, such as a swing between power supply levels, and provide one or more output signals at the same level at remote locations of an IC. However, transmission between a signal source and the remote locations can be by way of a small swing signal, or differential pair of small swing signals.

Referring now to FIG. 2B, a signal path according to another embodiment is shown in a block schematic diagram, and designated by the general reference character 250. A signal path 250 can include some of the same general structures as that of FIG. 2A, thus like structures are referred to by the same reference characters. Signal path 250 can differ from that of FIG. 2A in that it can include LV signal repeaters 252-0 and 252-1. A LV signal repeater (252-0 and 252-1) can be included in the event a global signal transmitter 202 lacks the drive strength for a given wiring. A LV receiver buffer (212-0 to 212-n) can receive a low voltage swing signal VG (or differential signals VG−/VG+), and in response thereto, output a signal at such a low swing level.

In this way, a signal path can receive an input signal having a large signal swing and provide one or more output signals at the same level at remote locations of an IC. However, transmission between a signal source and the remote locations can be by repeaters circuits operating at a small voltage swing.

Examples of FET buffer circuits that can be used in the various embodiments will now be described.

Referring now to FIG. 3A, a FET buffer circuit according to one embodiment 300 is shown in a schematic diagram. FET buffer circuit 300 can be a conventional complementary IGFET buffer (e.g., CMOS type buffer) that includes a p-channel IGFET P30 and an n-channel IGFET N30 with source-drain paths in series between a high power supply node 302 and a low power supply node 304. Voltage swings for input signal VIN(IGFET) and resulting output signal Vout(IGFET) can be essentially the power supply levels, which in one particular example can be between about 0 volts and 1.0 volt (i.e., about a 1.0 volt swing).

FIG. 3B shows a FET buffer circuit according to another embodiment. The FET buffer circuit 350 of FIG. 3B can be a complementary junction FET buffer that includes a p-channel JFET P35 and an n-channel JFET N35 with source-drain paths in series between a high power supply node 352 and a low power supply node 354. JFETs P35 and/or N35 can operate in an enhancement mode type operation, allowing for high impedance states when turned off. In more particular examples, JFETs P35 and/or N35 can include “back” gates in addition to front gates for greater control over channel conductivity. A JFET buffer circuit 350 operates at potentials below the p-n junction forward bias voltage for the material employed. In one particular case, JFET buffer circuit 350 can be fabricated in silicon, and thus operate below 0.7 volts, preferably at about 0.5 volts. As in the case of the IGFET buffer, voltage swings for input signal VIN(JFET) and resulting output signal Vout(JFET) can be essentially transitions between the power supply levels, which in one particular example can be between about 0 volts and 0.5 volt (i.e., about a 0.5 volt swing).

In this way, buffer circuits can provide output signals having an essentially rail-to-rail voltage swing for subsequent translation into smaller signal swing levels.

As understood from above, high voltage swing FET buffer circuits can operate in conjunction with low voltage swing LV circuits. Such LV circuits can perform various functions including (1) translate a relatively high voltage swing signal (e.g., greater than about 0.5 volts) into a low voltage swing signal (e.g., about 0.1 volts); (2) receive a low voltage swing signal and output the same (e.g., a repeater); (3) translate a low voltage swing signal into a high voltage swing signal. Very particular examples of such circuits will now be described.

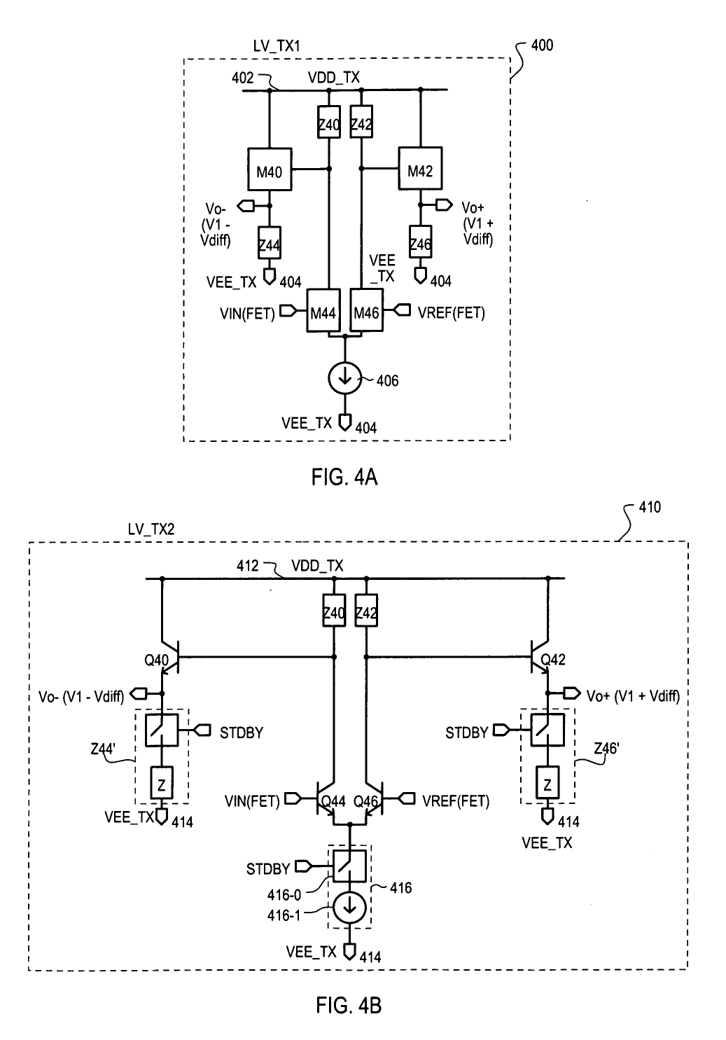

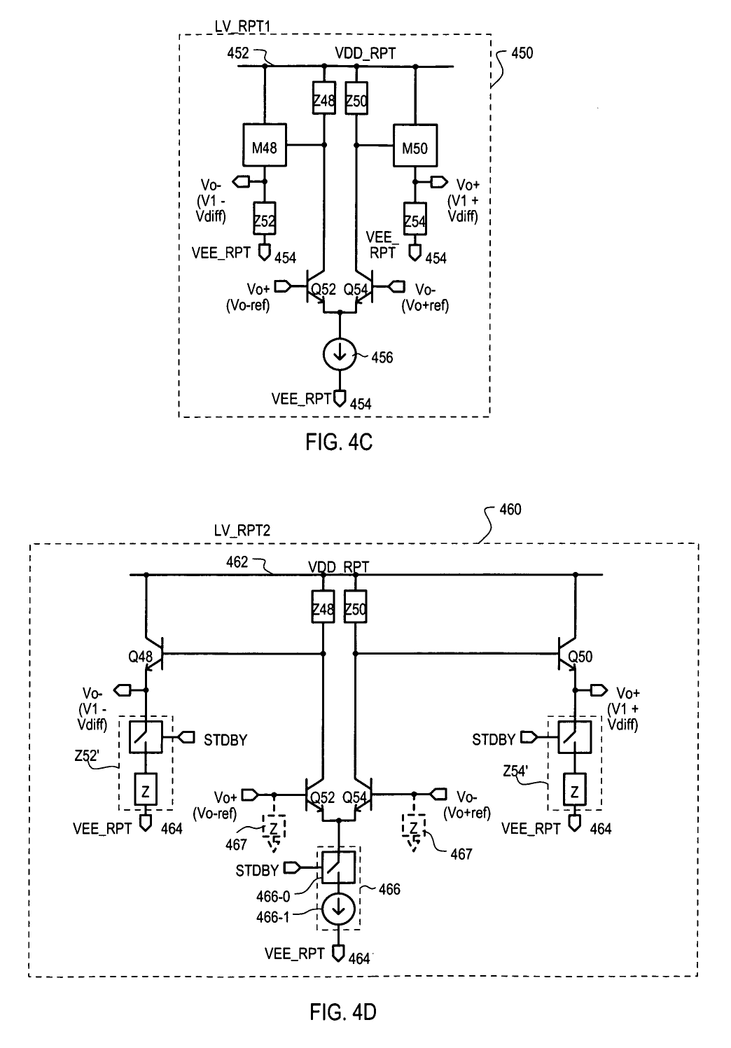

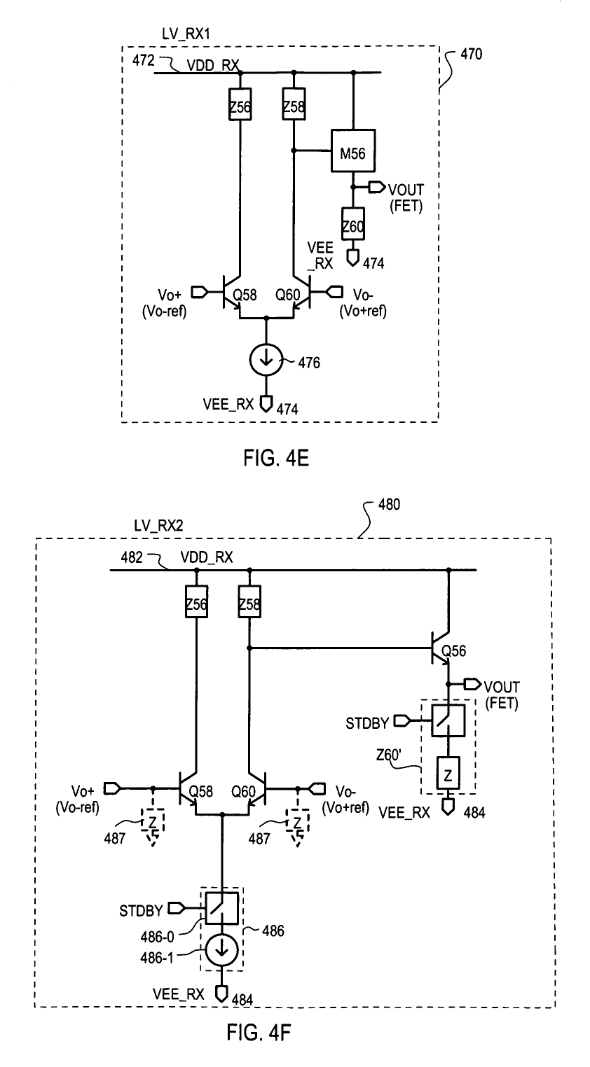

Referring now to FIG. 4A, one example of a LV transmission (TX) buffer, like that shown as 208 in FIGS. 2A/B is shown in a schematic diagram, and designated by the general reference character 400. ECL TX buffer 400 can be connected between a high power supply voltage node 402 and a second low voltage node 404, and can include a differential pair of transistors (BJTs) M44/M46, one or more driver transistors M40 and/or M42, and a current source 406.

Differential pair transistor M44 can have a control terminal that receives a high swing input signal VIN(FET), and a controllable impedance path connected to between a current source 406 and an impedance Z40. Transistor M46 has a control terminal that receives a high swing reference signal VREF(FET), and a controllable impedance path connected between to a current source 406 and an impedance Z42. Current source 406 can be connected between the current paths of transistors M44/M46 and a second low power supply node 404.

A LV TX buffer 400 can be configured to output a single ended signal (Vo− or Vo+), or a differential signal (Vo− and Vo+). In a single ended configuration, only one driver transistor M40 or M42 can be included depending upon which signal is output. In the differential configuration, both driver transistors M40/M42 can be included. If included, transistor M40 can have a control terminal connected to transistor M44, and a controllable impedance path connected between a high power supply node 402 and a second low power supply node 404 via an impedance Z44. Transistor M40 can provide a signal Vo−. Signal Vo− can vary between a potential V1 and V1−Vdiff.

If included, transistor M42 can include a control terminal connected to transistor M46, and a controllable impedance path connected between a high power supply node 402 and second low power supply node 404 via an impedance Z46. Transistor M42 can provide a signal Vo+. Signal Vo+ can vary between a potential V1 and V1+Vdiff. It is understood that if LV TX driver 400 has a differential configuration, signals Vo− and Vo+ can be essentially synchronous. That is, when signal Vo− transitions from V1 to V1−Vdiff, signal Vo+can transition from V1 to V1+Vdiff.

Any of power supply levels VDD_TXX, VEE_TX, impedance values Z40/Z42 and Z44/46, as well as current mirror 406 can be selected to set output voltage signal V1 and value Vdiff. In one particular arrangement, Vdiff can be no more than 200 mV, preferably about 100 mV. Input signal VIN(FET) can be a high voltage swing signal as described above (e.g., 1.0 volts or 0.5 volts). A reference voltage VREF(FET) can be at some level between the range of signal VIN(FET) (e.g., 0.5 volts, or 0.25 volts).

In this way, a LV TX buffer can translate a high voltage swing signal into a low voltage swing signal. A low voltage swing can be a single signal (e.g., Vo− or Vo+), or a differential pair (e.g., Vo−/Vo+).

Referring now to FIG. 4B, a more detailed example of a LV TX driver is shown in a schematic diagram and designated by the general reference character 410. LV TX driver 410 can differ from that of FIG. 4A in that driver transistors can be bipolar junction transistors Q40 and Q42. In addition, a current source 416 can be programmed into a low, or no current drawing state. In the very particular example, shown, a current source can include a current source circuit 416-1 and a control switch 416-0. In response to a signal STDBY, control switch 416-1 can be placed into a very high impedance state. In addition or alternatively, load impedances Z44′ and Z46′ can be programmable into low, or no current drawing states. In the very particular example of FIG. 4B, programmable impedances Z44′ and Z46′ can include a control switch that is enabled or disabled in response to a signal STDBY. In this way, a LV TX driver can be switched into a low current state.

The arrangement of FIG. 4B can be understood to be an emitter-coupled logic (ECL) type circuit.

Referring now to FIG. 4C, one example of a LV signal repeater, like that shown as 252-0/1 in FIGS. 2A/B is show in a schematic diagram, and designated by the general reference character 450. LV signal repeater 450 can have the same general construction as LV TX buffer shown in FIG. 4A. However, impedance values Z48, Z50, Z52, Z54 and current source 456 can be selected to provide a different operating point. More particularly, an LV signal repeater 450 can receive a low swing voltage signal (or pair of signals), and output a low voltage swing signal (or pair of signals). LV signal repeater 456 can include BJT devices Q52 and Q54 as a differential pair of input transistors. BJT devices (Q52 and Q54) can provide a high transconductance for detecting low voltage signal levels.

As in the case of LV TX buffer 400, a LV signal repeater 450 can have a single ended or differential configuration, both at an input or output. Thus, a LV signal repeater 450 can include one of transistors M48 or M50 configured for a single ended output (output only Vo− or Vo+), or both if configured for a differential output (Vo− and Vo+).

In this way, a LV signal repeater can translate a low voltage swing signal into another low voltage swing signal. A low voltage swing can be a single signal (Vo− or Vo+), or a differential pair (Vo−/Vo+).

Referring now to FIG. 4D, a more detailed example of a LV signal repeater is shown in a schematic diagram and designated by the general reference character 460. LV signal repeater 460 can differ from that of FIG. 4C in that driver transistors can be bipolar junction transistors Q48 and Q50. In addition, a current source 416, load Z52′ and/or load Z54′ can be switched off to provide a low, or no current draw state.

FIG. 4D can optionally include termination impedances 467 at one or both inputs. Termination impedances 467 can be selected to match an effective transmission line impedance presented by a conductive line carrying a signal to an input of LV TX driver 460.

The arrangement of FIG. 4D can also be understood to be an ECL type circuit.

Referring now to FIG. 4E, one example of a LV receiver (RX) buffer, like that shown as 212-(0 to n) in FIGS. 2A/B, is show in a schematic diagram and designated by the general reference character 470. ECL RX buffer 470 can have the same general construction as LV signal repeater shown in FIG. 4C. However, impedance values Z56, Z58, Z60, and current source 476 can be selected to provide a different operating point. More particularly, an LV RX buffer 470 can receive a low swing voltage signal (or pair of signals), and output a high voltage swing signal.

As in the case of LV signal repeater 450, a LV TX buffer 470 can have a single ended or differential input configuration. That is, an LV TX buffer 470 can receive a low voltage signal Vo− or Vo+, or both as inputs. LV TX buffer 470 can have a single ended output, biased to generate an output signal having a high voltage swing VOUT(FET). In one particular arrangement, a signal VOUT(FET) can have a voltage swing of about 1.0 volts or 0.5 volts.

In this way, a LV TX buffer can translate a low voltage swing signal into a high voltage swing signal. A low voltage swing can be a single signal (Vo− or Vo+), or a differential pair of signals (Vo−/Vo+).

Referring now to FIG. 4F, a more detailed example of a LV TX buffer is shown in a schematic diagram and designated by the general reference character 480. LV TX buffer 480 can differ from that of FIG. 4E in that a driver transistor can be bipolar junction transistors Q56. In addition, a current source 486 and/or impedance Z60′ can be switched off to provide a low, or no current draw state. LV TX buffer 480 can also include termination impedance 487 at one or both inputs of the buffer.

The arrangement of FIG. 4F is yet another example of an ECL type circuit.

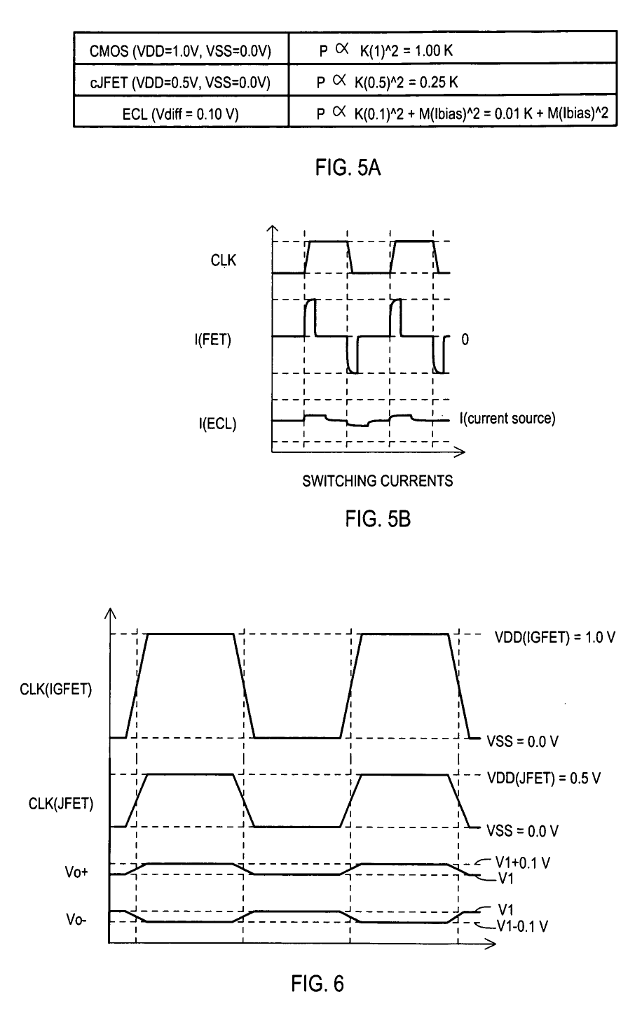

As noted above, providing for low swing voltage signals over longer signal transmission lengths of an integrated circuit device can provide power savings over conventional approaches. FIG. 5A shows a table illustrating very particular examples of power savings that can be achieved. The table of FIG. 5A includes a first row corresponding to a CMOS signal level that can vary between 0 volts and 1.0 volts. In such an arrangement, power consumption can be proportional to 1.00 K (where K is a constant). A second row shows a signal corresponding to a complementary JFET (cJFET) signal level that can vary between 0 and 0.5 volts. In this approach, as compared to the CMOS case, power consumption can ¼ that of the CMOS case. However, a last row of the table of FIG. 5A shows signals transmitted according to one embodiment. Such signals can have a swing of about 0.1 volts and include a static current draw component Ibias and some resistance constant M. This can result in power consumption a little over 1/100 that of the CMOS case.

In this way, signal transmission according to the various embodiments can provide substantial reduction in power consumption over conventional approaches.

In addition to improvements in power consumption, utilizing low voltage buffered global signaling arrangements like those described above can have advantageous current switching characteristics. Such advantages are represented in FIG. 5B.

FIG. 5B is a timing diagram showing a signal switching voltage waveform CLK, a FET buffer current switching waveform I(FET), and a low voltage (in this example an ECL) buffer current switching waveform I(ECL). Waveform CLK can represent a signal utilized to control switching. In particular, such a signal can be the input signal for a buffer circuit. Waveform I(FET) shows how a current may be drawn in a FET type buffer. Such a waveform shows that a great deal of current can be drawn as the device drives an output from one supply voltage level (e.g., 0 volts) to another (e.g., VDD of 1.0 volts or 0.5 volts). It noted that FET buffers may also have considerable leakage current (not shown) at smaller geometries.

In contrast to the waveform I(FET), the waveform I(ECL) shows an essentially constant current draw, based upon a biasing current source of the ECL circuit (e.g., like that shown as 406, 456 and 476 in FIGS. 4A to 4C). Thus, ECL buffers may have a far smaller current draw at the switching point of a transmitted signal, and a far more constant current draw over time.

It is noted that for consistently switching operations, like those for a timing clock and the like, ECL buffering can present an overall smaller current draw than FET type buffers.

In this way, a global signaling arrangement can provide a more constant and/or smaller current draw, particularly for regular switching signals, such as clock signals.

Referring now to FIG. 6, a timing diagram shows signal levels according to one very particular embodiment. FIG. 6 shows a first high voltage signal CLK(IGFET), a second high voltage signal CLK(JFET), a first low voltage signal Vo+, and a second low voltage signal Vo−. Signal CLK(IGFET) can represent a CMOS signal level that varies between 0 V and 1.0 V. Signal CLK(JFET) can represent a JFET signal level that varies between 0 V and 0.5 V. Signals Vo+ and Vo− can represent signals output by low voltage buffers or repeaters. In a single ended arrangement, one such signal can be used (Vo− or Vo+). In a differential arrangement, both signals Vo− and Vo+ can be used together.

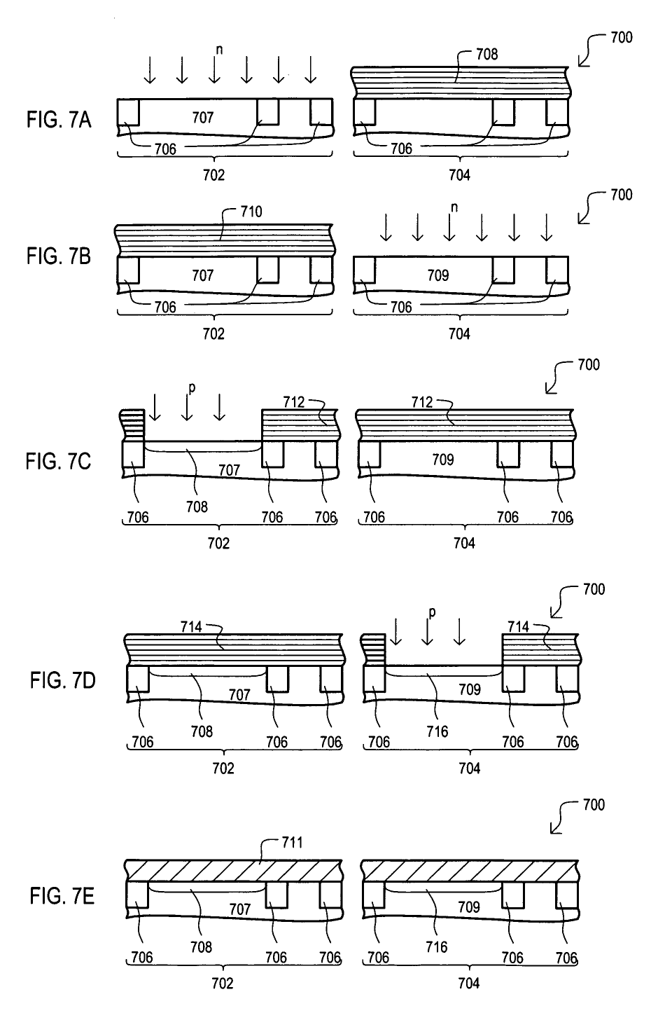

While the above embodiments have shown arrangements in which bipolar junction transistor (BJT) buffer circuits can be utilized in conjunction with IGFET type circuits, it can be particularly advantageous to incorporate such BJT circuits into complementary JFET circuits. One such approach is shown in FIGS. 7A to 7C which show various views of a device structure that can serve as either a JFET or a BJT device. Thus, an integrated circuit manufacturing process that fabricates JFET devices can easily incorporate such BJT devices to form ECL buffers circuits and the like.

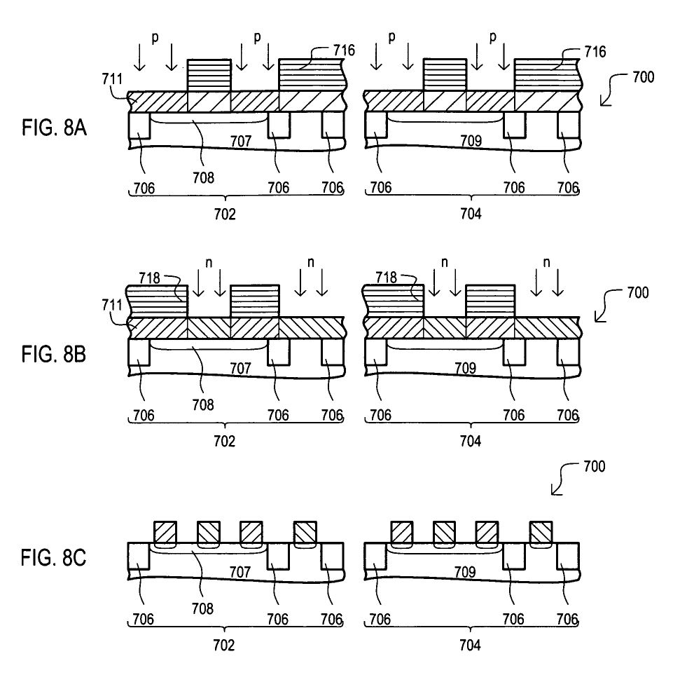

Referring now to FIGS. 7A to 8C, methods of forming four terminal integrated circuit device structures that can serve as either a JFET or a BJT are illustrated in a series of side cross sectional views.

Referring now to FIG. 7A, an integrated circuit device 700 can include a substrate having a first portion 702 and a second portion 704. Isolation structures 706 can be formed within first and second portions (702 and 704) to create active areas for the formation of either JFET or BJT devices. In one very particular arrangement, isolation structures can be formed with shallow trench isolation (STI) techniques. Optionally, a first portion 702 can be subject to a JFET well formation step, such as an ion implantation step. In FIGS. 7A to 8C, a JFET can be a p-channel JFET. Accordingly, a well formation step can create an n-type well 707. At the same, time a second portion 704 can be masked with an implant mask 708.

Referring now to FIG. 7B, a method can optionally include a collector formation step within the second portion 704. Such a step can be included to provide a different doping profile for a BJT collector versus that for a JFET well, and can be an ion implantation step. During such a step, a first portion 702 can be masked with an implant mask 710. In FIGS. 7A to 8C, a BJT can be an npn BJT. Accordingly, a collector formation step can create an n-type collector 709.

Referring now to FIG. 7C, a first portion 702 can be subject to a JFET channel formation step, such as another ion implantation step. A channel mask 712 can provide an opening at locations where a JFET channel is to be formed. A channel impurity can be opposite to that of a well impurity, and thus can create a p-type channel 708 in the example of FIG. 7C. At the same, time a second portion 704 can be masked with channel mask 712.

Referring now to FIG. 7D, a second portion 704 can be subject to a BJT base formation step, such as another ion implantation step. A base mask 714 can provide an opening at locations where a BJT base is to be formed. A channel impurity can be opposite to that of a collector impurity, and thus the formed base 716 is p-type. A first portion 702 can be masked with base mask 714.

In alternate embodiments, an impurity creation step can follow the formation of a channel and/or base, to form JFET source/drain or gate regions in a substrate, or BJT emitter and collector regions in the same substrate. Such regions can make physical contact with subsequently formed surface electrodes, as will be described below.

Referring now to FIG. 7E, a semiconductor electrode material 711 can be formed over first and second portions (702 and 704). An electrode material 711 can be a material capable of forming a pn junction with a substrate. Accordingly, in particular examples, a semiconductor material 711 can be silicon, preferably polycrystalline silicon (polysilicon), formed over and in contact with a silicon substrate including portions 702 and 704.

Referring now to FIG. 8A, first and second portions (702 and 704) can be subject to an electrode doping step. Such a step can dope portions of a semiconductor material 711 to a particular conductivity type and concentration to form certain electrodes of a JFET, BJT, or both. In the very particular example of FIG. 8A, electrodes can be doped to form source and drain electrodes of a JFET, and base electrodes of a BJT. While FIG. 8A shows base electrodes formed at the same time as source/drain electrodes, different doping steps can be used for these structures in alternate embodiments.

Referring now to FIG. 8B, first and second portions (702 and 704) can be subject to a second electrode doping step. Such a step can dope portions of a semiconductor material 711 to a different conductivity type than that of the step shown in FIG. 8A to form other electrodes of a JFET, BJT or both. In the very particular example of FIG. 8B, electrodes can be doped to form gate and well electrodes of a JFET and emitter and collector electrodes of a BJT. In alternate embodiments, an emitter and collector can be formed with different doping steps.

Referring now to FIG. 8C, first and second portions (702 and 704) can be subject to an electrode patterning step. Such a step can include etching doped semiconductor material 711 into electrode structures. Such as step can be reactive ion etch, as but one example. In addition forming a more conductive layer over all or portions of such electrodes, such as a silicide layer, could be formed prior to, or after such a patterning step. Subsequently, an integrated circuit device 700 can be subject to heat treatment step that can cause impurities to out diffuse from electrodes into a substrate below.

In this way, both JFET and BJT devices can be formed in the same substrate. Such an approach can be utilized to form bipolar devices utilized in a low voltage transmitter, low voltage repeater, and/or low voltage receiver, as described above.

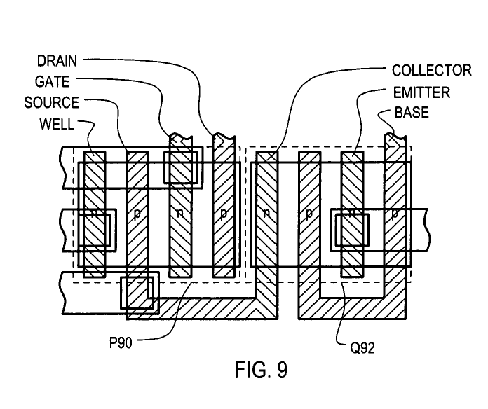

Referring now to FIG. 9, a semiconductor device having integrated JFET and BJT devices is shown in a top plan view, and designated by the general reference character 900. A semiconductor device 900 can have JFET device P90 and npn BJT Q92. A same layer(s) utilized to form electrodes can serve as a first layer of interconnect between the transistors.

It is noted that FIG. 9 shows an arrangement in which dimensions of the FET and BJT structures can be essentially the same size. However, in some embodiments it may be desirable to increase the driving capability of a BJT device. This can be advantageously done by increasing the base-emitter area of the device, which can be equivalent to increasing the channel length and/or width of a FET structure. Advantageously, such an increase in drive strength may not include a corresponding increase in channel leakage, as can be the case for IGFET type drivers.

It is understood that FIG. 9 can be a physical representation of a circuit, or a fabrication mask set, or mask data value embodied on a machine readable media.

While the above embodiments have shown devices and structures for generating low voltage swing signals in an integrated circuit, the present invention can also include systems and methods for designing such integrated circuits including such devices and structures.

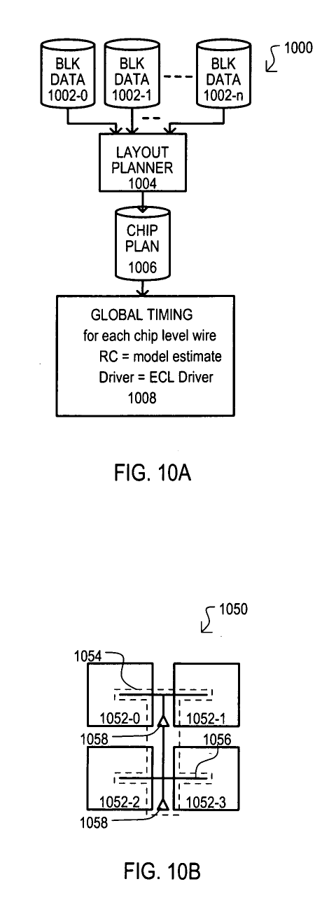

Referring now to FIG. 10A a method and system for designing an integrated circuit device is shown in a block diagram, and designated by the general reference character 1000. A system 1000 can include a number of block design databases 1002-0 to 1002-n, a layout planner 1004, a chip plan database 1006, and a global timing 1008. Block design databases (1002-0 to 1002-n) can include data for different blocks for inclusion into a single integrated circuit.

A layout planner 1004 can utilize block design databases (1002-0 to 1002-n) to generate a chip plan 1006. In particular, layout planner 1004 can arrange blocks into a single plan, including actual or estimated signal input/output positions for such blocks. Thus, a chip plan 1006 can include actual or estimated block areas and positions, along with input points for such blocks (i.e., signal, power supplies, etc.). A layout planner 1004 can also include a top level wiring plan for interconnecting blocks to one another.

A global timing 1008 can check the timing between blocks for the overall chip. However, unlike cases in which global timing can be based on models utilizing full swing drivers (e.g., CMOS or cJFET drivers), a global timing 1008 can model timing based on LV drivers, like those described above, including lower voltage swing levels.

In one particular method, a global timing 1008 can be checked against a desired value. If a global timing 1008 does not meet the value (e.g., timing, fan-out, noise immunity), a chip level timing can be adjusted. Such an adjustment can include, as but a few examples, increasing LV buffer drive strength (e.g., increasing transistor beta by implementing larger base-emitter junction area), adding LV repeaters, increasing clock line dimensions, changing clock line materials, adding FET buffering.

In this way, a system and method can have a global timing based on LV buffers rather than FET based buffers.

FIG. 10B is a timing diagram showing an integrated circuit timing model 1050 according to one embodiment. A timing model 1050 can include blocks 1052-0 to 1052-3 coupled to a global wiring network 1054. A global wiring network 1054 can include wiring legs (one of which is shown as 1056) and a number of buffer models 1058. Buffer models 1058 can be LV based buffers.

In this way, a chip design and/or simulation can have global timing (e.g., timing of signals between blocks) based on LV buffers.

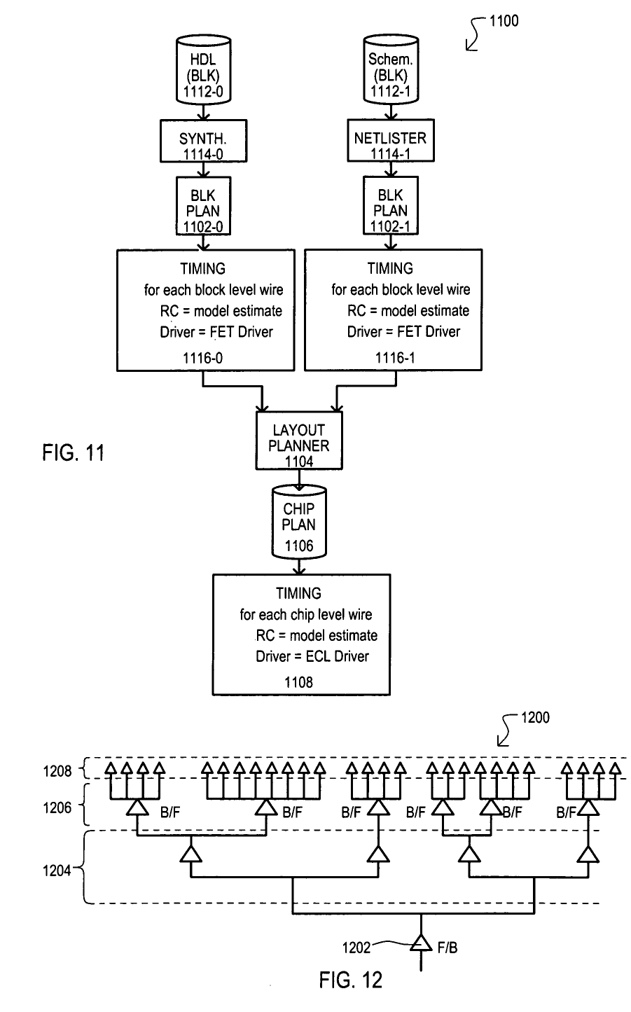

Referring now to FIG. 11, a method and system for designing an integrated circuit device according to another embodiment is shown in a block diagram, and designated by the general reference character 1100. A system 1100 can include some of the same general sections as FIG. 10A, thus like sections are referred to by the same general reference character, but with the first two digits being “11” instead of “10”.

FIG. 11 can differ from that of FIG. 10A in that a block design database 1102-0 and 1102-1 can be synthesized from a hardware design language (HDL) representation 1112-0 with a synthesizer program 1114-0. A block design database 1102-1 can also be created by a netlister program 1114-1 from a schematic design 1112-1.

In addition, a system 1100 can include a block timing 1116-0 and 1116-1 for each block design database (1102-0 and 1102-1). A block timing (1102-0 and 1102-1) can check the timing within each block. Such timing can be based on FET signal drivers, and not bipolar based drivers, such as LV buffers. Such block timing can help a layout planner 1104 optimally place signal generating points (sources) and signal reception points (sinks).

In this way, a block timing can be based in FET driver circuits, while a global timing can be based on bipolar based drivers, preferably ECL buffers like those described above.

While the various embodiments can be used for the transmission of essentially any signal between blocks of an integrated circuit, such methods and structures may preferably used to transmit a global clock signal for timing operations within and between blocks of an integrated circuit. One very particular example of such a clock arrangement is shown in FIG. 12.

Referring now to FIG. 12, a clock “tree” according to one embodiment is shown and designated by the general reference character 1200. A clock tree 1200 can include a clock source 1202, a clock distribution network 1204, conversion buffers 1206, and clock sinks 1208. A clock source 1202 can be a representation of a circuit that translates a high voltage swing signal to drive a low voltage swing signal on clock distribution network 1204. More particularly, clock source 1202 can represent a circuit that translates conventional FET level signals to BJT driven levels. Even more particularly, a clock source 1202 can be a FET to LV conversion circuit, like a global signal transmitter 202 of FIGS. 2A and 2B.

A clock distribution network 1204 can represent signal wiring for carrying a clock signal from clock source 1202 to conversion buffers 1206. For example, a clock distribution network 1204 can have resistance-capacitance models based on clock line length and/or line type. It is noted that for a differential clock source 1202 a clock distribution network can include dual signal lines.

Conversion buffers 1206 can be a representation of a circuit that translates a low voltage swing signal into a high voltage swing signal. More particularly, conversion buffers 1206 can represent circuits that translate bipolar circuit generated signals into conventional FET level signals. Even more particularly, conversion buffers 1206 can be LV to FET circuits like translator circuits (204-0 to 204-n), shown in FIGS. 2A and 2B. Conversion buffers 1206 can drive clock sinks 1208.

Of course, a clock distribution network 1204 can include LV clock repeater models in addition to wiring models.

In this way, clock trees can be designed and simulated that include clock sources that receive a FET based input signals, convert such signals for LV based drivers for transmission throughout the majority of the clock tree 1200, and then convert such signals from that of LV based drivers back to FET based driver levels.

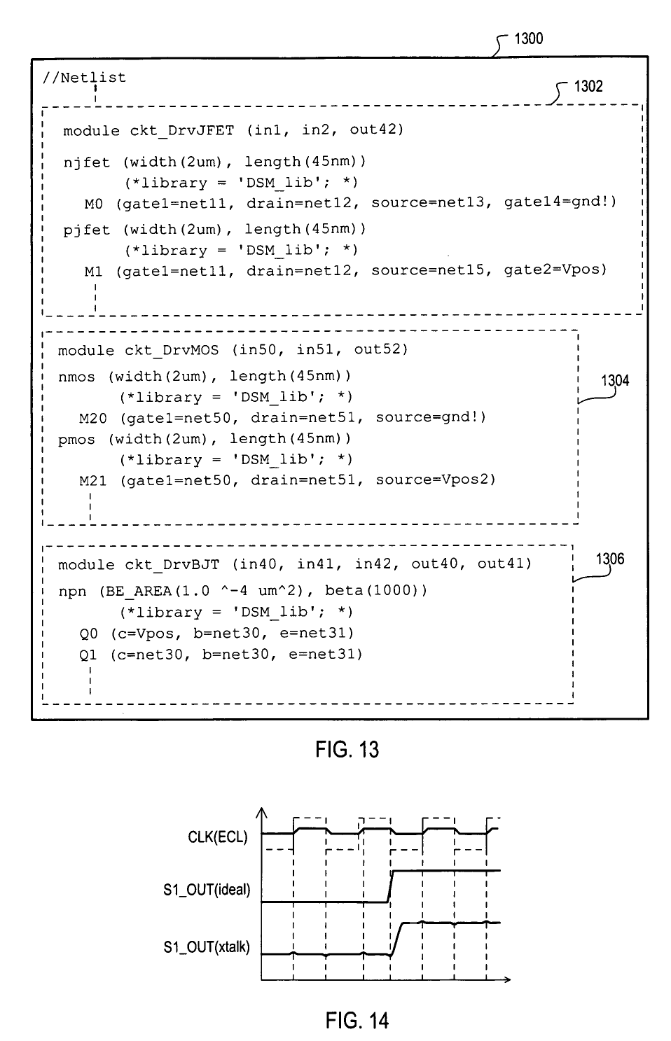

While the present invention can include integrated circuits, devices, systems and methods. the invention may also include designs embodied on machine readable media. One such example is shown in FIG. 13.

Referring now to FIG. 13, a design according to one particular embodiment is shown as a netlist in text form and designated by the general reference character 1300. A design 1300 can include declarations of element types and associated interconnections arranged into modules.

In the particular example shown, a design 1300 can include a JFET driver module “ckt_DrvJFET” 1302 and a BJT driver module “ckt_DrvBJT” 1306. Optionally, a design 1300 can include an IGFET driver module “ckt_DrvMOS” 1304. A JFET driver module 1302 can include JFET devices interconnected to drive an output node (out42) between power supply levels (Vpos and gnd!). Thus, a JFET driver module 1302 can output a relatively large voltage swing signal. In one arrangement, a JFET driver module 1302 can have a structure like that shown in FIG. 3B.

A BJT driver module “ckt_DrvBJT” 1306 can include BJT devices interconnected to drive an output node (out41) at a lower voltage swing level. In one arrangement, a BJT driver module 1306 can have a structure like that shown in any of FIGS. 4A to 4C.

The particular example of FIG. 13 also includes the incorporation of IGFET (e.g., MOS) type transistors into the same integrated circuit. Consequently, the design 1300 can include IGFET driver module “ckt_DrvMOS” 1304. An IGFET driver module 1304 can include IGFET devices interconnected to drive an output node (out52) between higher power supply levels (Vpos2 and gnd!). Thus, an IGFET driver module 1304 can output a large voltage swing signal.

It is understood that JFET devices and BJT devices declared in FIG. 13 can correspond all or in part to elements like those shown in FIGS. 7A to 7C and/or 8A to 8C.

In this way, a design can include large voltage swing based modules, such as modules with active elements only composed of FET devices, with selected nodes being driven at lower voltage swing levels and translated from such lower swing levels into higher swing levels by modules with active elements composed of BJT devices.

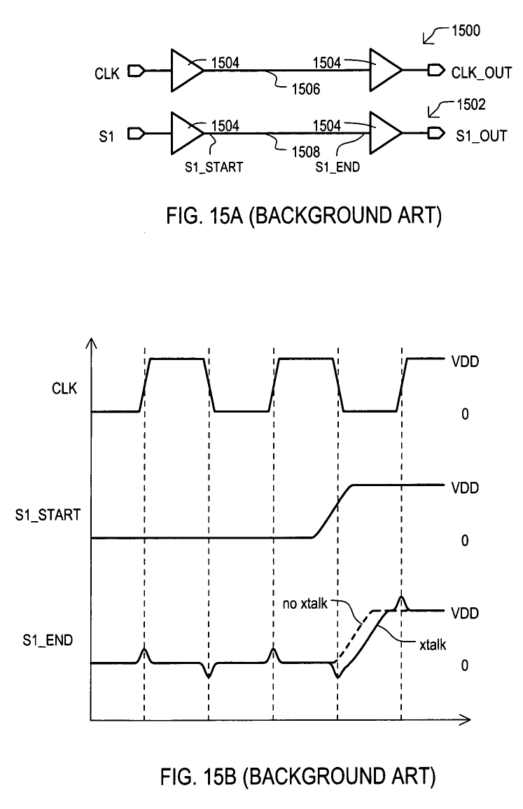

Referring now to FIG. 14, a timing diagram is shown that can be compared to the conventional response represented by FIG. 15B. FIG. 14 shows waveforms corresponding to a clock signal CLK(ECL) that can be transmitted according to any of the various embodiments shown above. Superimposed onto the signal CLK(ECL) can be a conventional high voltage swing clock signal, shown by a dashed line waveform. Waveform S1_OUT (ideal) can be an ideal output signal from signal path. That is, S1_OUT can be a desired result. Waveform S1_OUT(xtlk) can represent an output signal resulting from unwanted crosstalk, but with the reduced voltage swing of signal CLK(ECL).

As shown, because signal CLK(ECL) has a lower voltage swing, a resulting impact of crosstalk on signal S1_OUT(xtlk) can be reduced over conventional approaches.

In this way, adverse effects of capacitive coupling can be reduced utilizing signaling according to the various embodiments. It is also noted that such reductions in parasitic rising and falling of a signal can be particularly advantageous in JFET based integrated circuits, which seek to avoid uncontrolled voltage spikes that can forward bias p-n junctions within such JFET devices.

Still further, by including ECL related buffers to generate lower voltage swing signals, an input impedance and/or signal reflections can be reduced as compared to a FET based driver circuits.

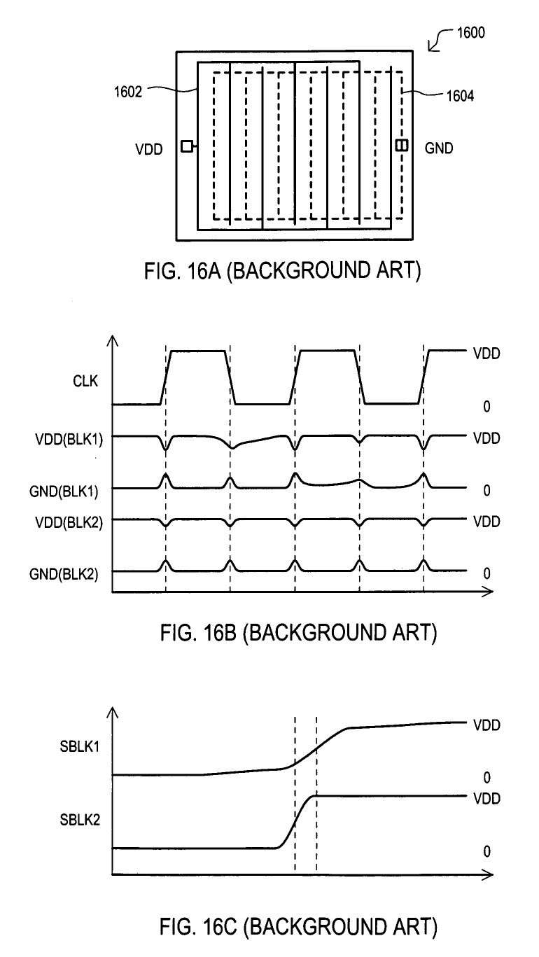

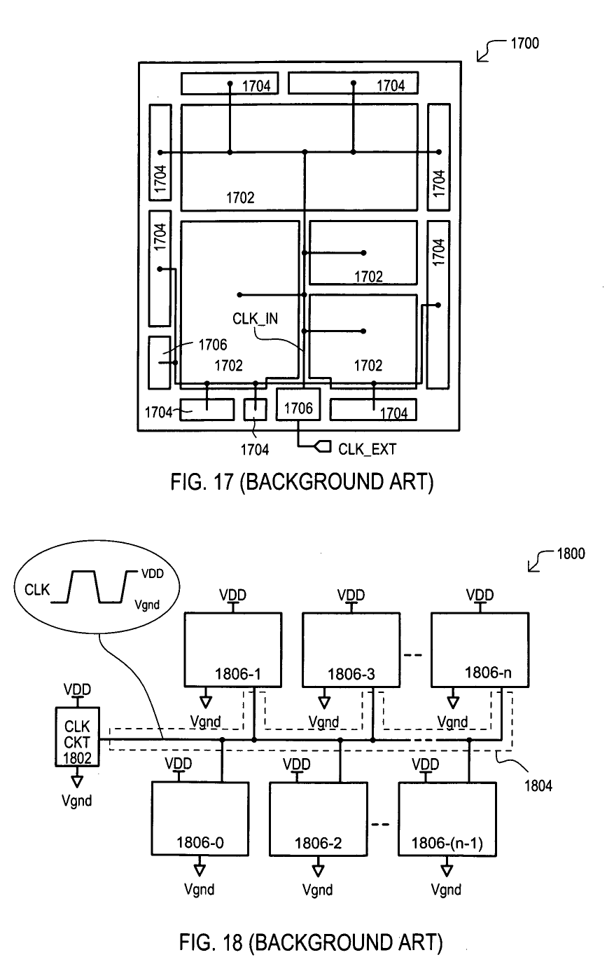

Referring now to FIGS. 19A-0 to 19N, more methods for forming four terminal integrated circuit device structures that can serve as a JFET or BJT are illustrated in a series of side cross sectional views. FIGS. 19A-0 to 19P show the formation of an n-channel JFET in conjunction with an npn BJT. However, as will be explained at a later point herein, the same approach can be used to form a p-channel JFET and/or pnp BJT.

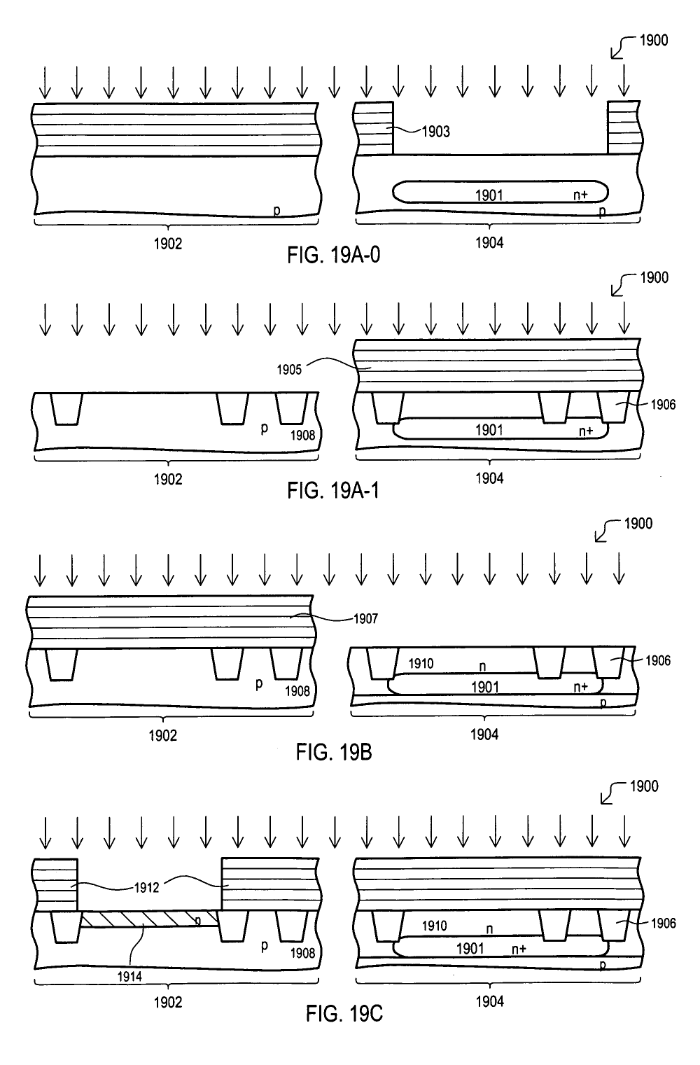

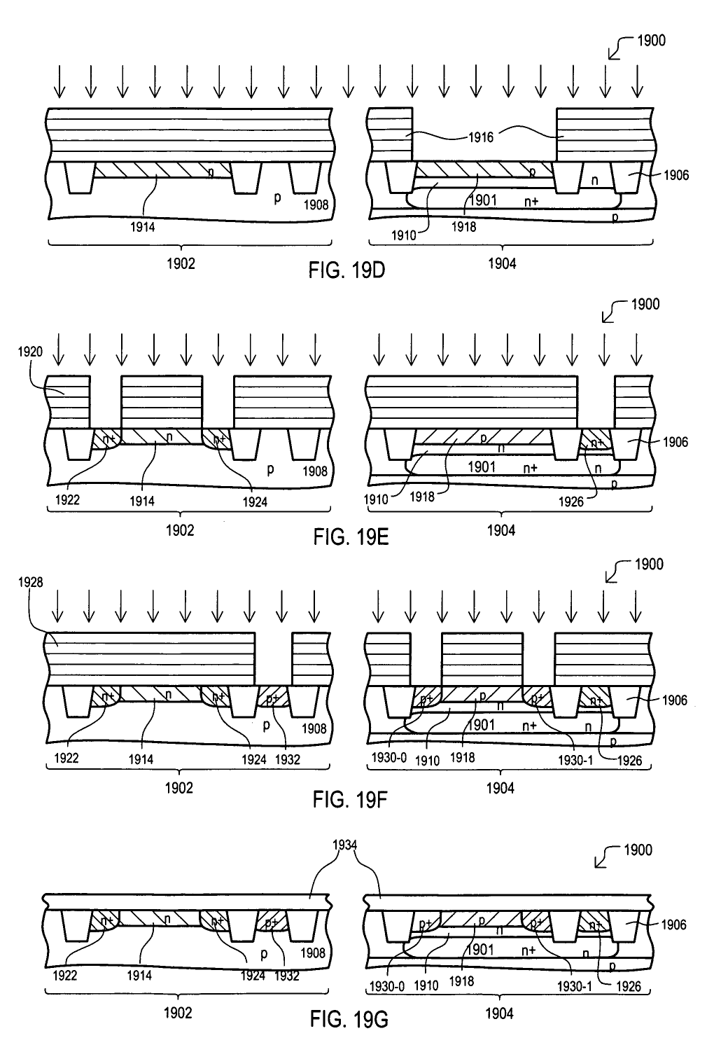

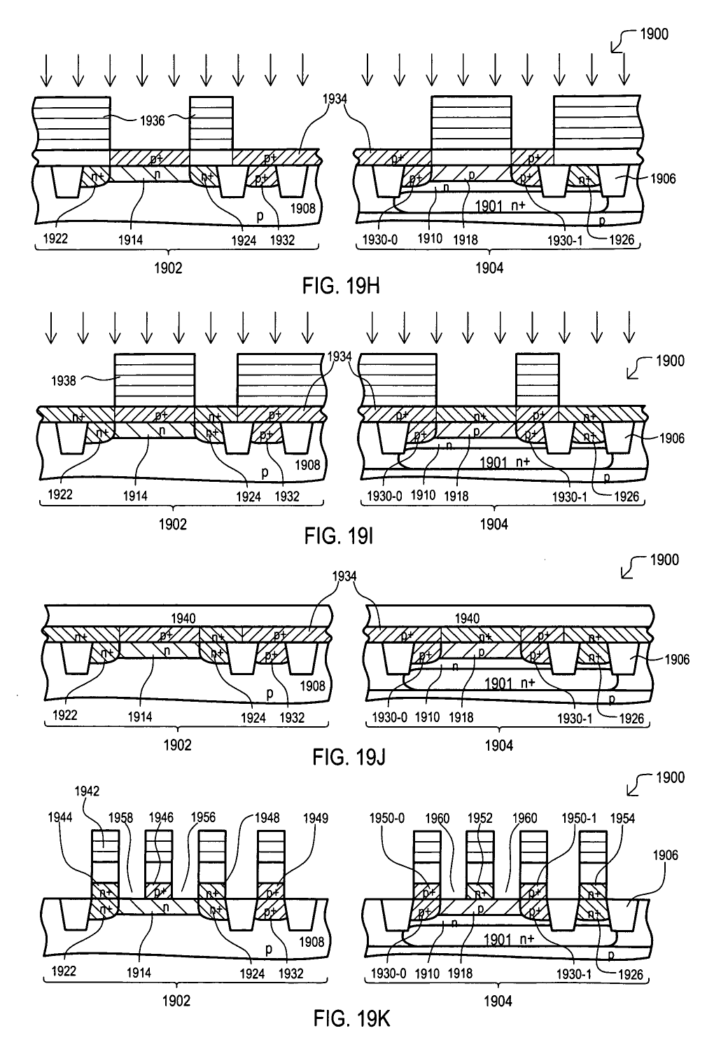

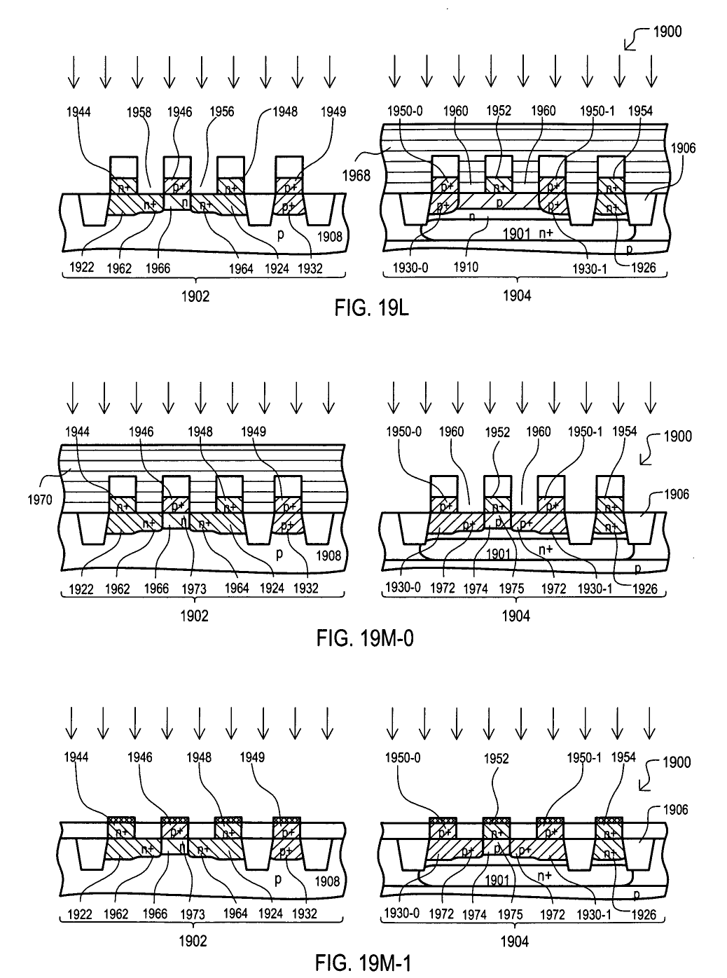

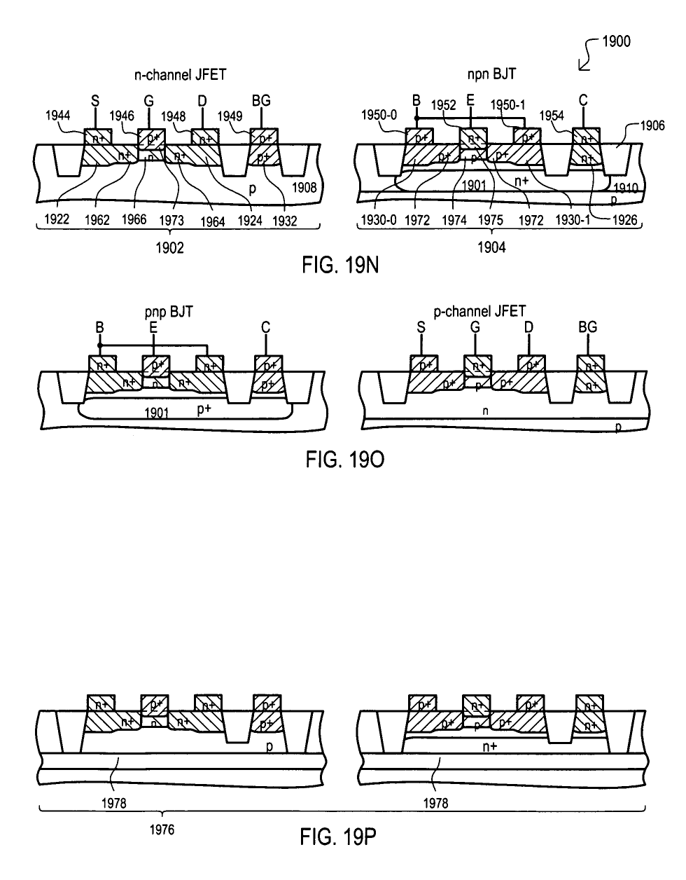

Referring now to FIG. 19A-0, an integrated circuit device 1900 can include a substrate having a first portion 1902 and a second portion 1904. FIG. 19A-0 shows an ion implantation step for forming a “buried” layer 1901 that can serve as a sub-collector region for a BJT device. A buried layer mask 1903 can be formed over a portion of the substrate in which a BJT device is to be formed, which in this example is the second portion 1904. In the example shown, a BJT will be an npn BJT, thus such a step can form an n+ buried layer 1901.

Referring now to FIG. 19A-1, isolation structures (one shown as 1906) can be formed within first and second portions (1902 and 1904) to create active areas for the formation of JFET or BJT devices. In one very particular arrangement, isolation structures can be formed with shallow trench isolation (STI) techniques. FIG. 19A-1 shows an optional field ion implantation step (ion implant) that can adjust the conductivity of a p-type substrate 1908 within first portion 1902 while second portion 1904 is masked by implant mask 1905. It is noted that a p-type substrate 1908 can be a “bulk” substrate or a p-well formed in an n-well (i.e., a “triple well” process).

FIG. 19B shows another optional field ion implant that can adjust the conductivity of an n-type substrate 1910 within second portion 1904 while a first portion 1902 is masked by implant mask 1907. Because n-type substrate 1910 can from part of a resulting npn BJT device, such a step can be used to provide a desired collector conductivity.

It is noted that an n-type substrate 1910 can be an n-well formed in p-type substrate. In addition, an n-type substrate 1910 in combination with buried layer 1901 can form a collector region within a substrate.

Referring now to FIG. 19C, a first portion 1902 can be subject to a JFET channel formation step, such as another ion implant. A channel mask 1912 can provide an opening at locations where an initial JFET channel is to be formed. A channel impurity can be opposite to that of a substrate impurity, and thus can create an initial n-type channel 1914 in the example of FIG. 19C. At the same, time a second portion 1904 can be masked from the implant by a channel mask 1912.

Referring now to FIG. 19D, a second portion 1904 can be subject to a BJT base formation step, such as another ion implant. A base mask 1916 can provide an opening at locations where an initial BJT base channel is to be formed. A channel impurity can be opposite to that of a substrate impurity, and thus can create an initial p-type channel 1918 in the example of FIG. 19D. At the same, time a first portion 1902 can be masked from the implant by a base mask 1916.

Referring now to FIG. 19E, at least a first portion 1902 can be subject to a source/drain ion implantation step. Such a step can include forming a source/drain mask 1920, which can provide openings at locations on the substrate where source and drain electrodes will be formed. In the particular example shown, a collector contact region can also be formed, thus source/drain mask 1920 can include an opening at a substrate location in second portion 1904 where a collector electrode is to be formed. Due to the particular device conductivity types illustrated (i.e., a n-channel JFET and npn BJT), heavily doped n+ regions can be formed using source/drain mask 1920. Such n+ regions can include a first source region 1922, a first drain region 1924, and a collector contact region 1926. An initial n-type channel 1914 can have a lower doping concentration than first source and drain regions (1922 and 1924). In other embodiments, a collector contact region 1926 may be formed separately with a different ion implant dose and/or energy than that used for first source and drain regions (1922 and 1924).

Referring now to FIG. 19F, a second portion 1904 can be subject to a base contact ion implantation step. Such a step can include forming a base contact mask 1928, which can provide openings at locations on the substrate where one or more base electrodes will be formed. In the particular example shown, a well (or back gate) contact region can also be formed for the JFET device, thus base contact mask 1928 can include an opening at a substrate location in first portion 1902 where contact to a well for the JFET is to be formed. Due to the particular device conductivity types illustrated, heavily doped p+ regions can be formed, including base contact portions 1930-0 and 1930-1, and well contact region 1932. An initial base region 1918 can have a lower doping concentration than base contact portions (1930-0 and 1930-1). In other embodiments, a well contact region 1932 may be formed with a separate ion implant step.

Referring now to FIG. 19G, a semiconductor electrode material 1934 can be formed over first and second portions (1902 and 1904). An electrode material 1934 can be silicon, preferably polycrystalline silicon (polysilicon), formed over and in contact with a silicon substrate that includes portions 1902 and 1904.

Referring now to FIGS. 19H and 19I, first and second portions (1902 and 1904) can be subject to an electrode layer doping step. Such a step can dope portions of an electrode material 1934 to a particular conductivity type and concentration. Such differently doped electrode layer regions can correspond to particular electrode structures in finished JFET and BJT devices. FIG. 19H shows a p+ doping step that uses a p+ electrode mask 1936. Similarly, FIG. 19I shows an n+ doping step that uses an n+ electrode mask 1938.

Referring now to FIG. 19J, a masking layer 1940 can be formed over semiconductor electrode material 1934. Such a masking layer 1940 can be suitable to mask the underlying electrode material from subsequent implant steps. A masking layer 1940 can be formed from silicon dioxide, silicon nitride, or silicon oxynitride as but a few examples.

Referring now to FIG. 19K, first and second portions (1902 and 1904) can be subject to an electrode patterning step. Such a step can include using an electrode etch mask 1942 to selectively, and anisotropically etch through masking layer 1940 and electrode material 1934 (and a silicide layer, if included) to expose a surface of the substrate below. A resulting structure can include a source electrode 1944, a gate electrode 1946, a drain electrode 1948, a well electrode 1949, base electrode portions 1950-0/1, emitter electrode 1952, and collector electrode 1954. Each of these electrodes (1944 to 1954) can have a corresponding portion of masking layer 1940 formed on its top surface.

Referring still to FIG. 19K, it is noted that a gate electrode 1946 can be separated from a drain electrode 1948 by a drain separation space 1956, and separated from a source electrode 1944 by a source separation space 1958. In a similar fashion, an emitter electrode 1952 can be separated from base electrode portions 1950-0/1 by an emitter separation space 1960.

Referring now to FIG. 19L, a first portion 1902 can be subject to a self-aligned source/drain ion implantation step. Such a step can include forming an n+ region in the first portion 1902 using source, drain and gate electrodes (1944 to 1946) (and their corresponding masking layer portions) as an ion implant mask. A second portion 1904 can be covered by mask 1968. As a result, an n+ source extension region 1962 can be formed below source separation space 1958 and an n+ drain extension region 1964 can be formed below drain separation space 1956. This can result in channel region 1966 being formed below gate electrode 1946 and adjacent to source extension region 1962 on a first side, and adjacent to drain extension region 1964 on an opposing second side.

Referring now to FIG. 19M-0, a second portion 1904 can be subject to a self-aligned base ion implantation step. Such a step can include forming a p+ region in the second portion 1904 using base and emitter electrodes (1950-0/1 and 1952) (and their corresponding masking layer portions) as an ion implant mask. A first portion 1902 can be covered by mask 1970. As a result, a p+ base extension region 1972 can be formed below emitter separation space 1960. This can result in a lighter doped base region 1974 being formed below emitter electrode 1952 and adjacent to base extension region 1972.

Referring to FIG. 19M-1, integrated circuit device 1900, a conductive layer 1980 (i.e., more conductive than semiconductor electrode material) can be formed over a top portion or more, of electrodes 1944, 1946, 1948, 1949, 1950-0/1, 1952, and 1954. As but one example, a conductive layer 1980 can be a silicide layer formed on a top surface of the electrodes, after an isolation film 1982 has been formed between electrodes.

Referring now to FIG. 19N, an integrated circuit device 1900 can be subject to a heat treatment that allows implanted regions to outdiffuse. In particular, and unlike conventional arrangements, dopants in emitter electrode 1952 and gate electrode 1946 can outdiffuse from the electrode material into the substrate below. As a result, a first portion 1902 can include a p+ gate region 1973 that extends into the substrate below the gate electrode 1946, and second portion 1904 can include an n+ emitter region 1975 that extends into the substrate below the emitter electrode 1952. FIG. 19N shows a semiconductor device following such a heat treatment, and the removal of masking layers on top surfaces of the electrodes. As shown, an n-channel JFET device can be formed in first portion 1902 and an npn BJT device can be formed in second portion 1904. Locations for various terminal connections of such devices are also shown in FIG. 19N, including a source connection (S), gate connection (G), drain connection (D), back gate (or well) connection (BG), base connection (B), emitter connection (E), and collector connection (C).

While FIGS. 19A to 19N show the formation and resulting structure for a n-channel JFET and npn BJT, devices of the opposite conductivity type can be formed in the same manner, using opposite doping of suitable concentration and energy.

FIG. 19O shows an example of a pnp BJT and p-channel JFET that can be formed using the approach shown in FIGS. 19A to 19N. As understood by comparing FIG. 19O with 19N, BJT and JFET devices can have the same general structure. Thus, such devices can be manufactured together without special process steps being used for one device and not the other.

FIG. 19P shows the same general structures as FIG. 19N, but formed with a semiconductor-on-insulator substrate 1976 which can include an insulating layer 1978 that extends in a direction parallel to a substrate surface.

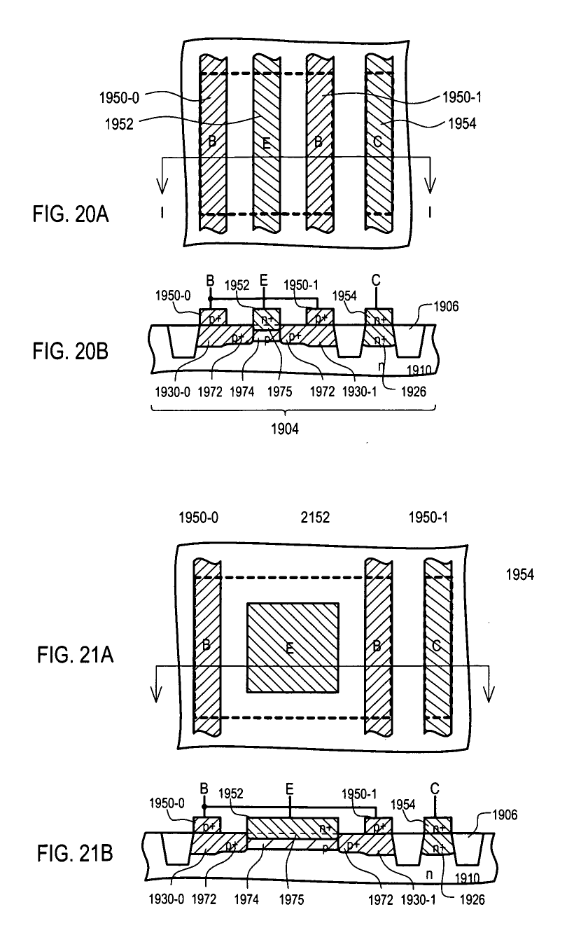

Referring now to FIGS. 20A and 20B, one example of the npn BJT structure shown in FIG. 19N is illustrated in a top plan view (FIG. 20A) and a side cross sectional view (FIG. 20B, taken along line I-I of FIG. 20A). In the example shown, a length of emitter electrode 1952 (the length being taken in the horizontal direction of FIGS. 20A and 20B) can be the same as, or similar to that of base electrode portions 1950-0/1.

Referring now to FIGS. 21A and 21B, another example of an npn BJT structure is illustrated in a top plan view (FIG. 21A) and a side cross sectional view (FIG. 21B, taken along line I-I of FIG. 21A). FIGS. 21A and 21B show the same general arrangement as FIGS. 20A and 20B, but with a larger emitter electrode 2152. Such a larger emitter electrode 2152 can provide for greater driving capability for the BJT device.

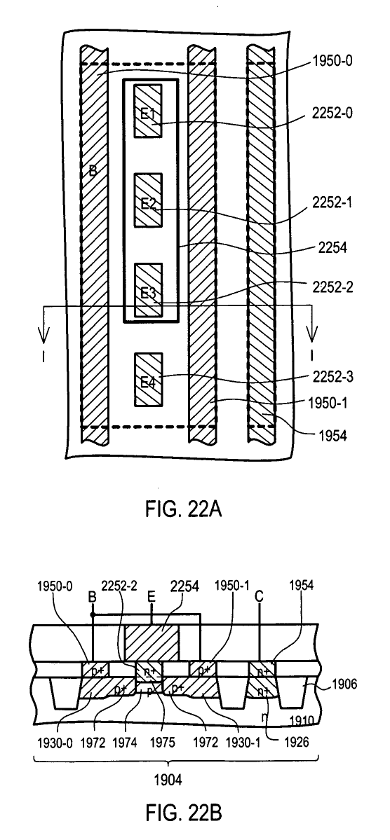

Referring now to FIGS. 22A and 22B, another example of an npn BJT structure is illustrated in a top plan view (FIG. 22A) and a side cross sectional view (FIG. 22B, taken along line I-I of FIG. 22A). FIGS. 22A and 22B show the same general arrangement as FIGS. 20A and 20B, but with multiple emitter electrodes 2252-0 to 2252-3. In such an arrangement, base/emitter area can be varied by conductively connecting greater or fewer numbers of emitter electrodes together. In the particular example of FIGS. 22A/B, emitter electrodes 2252-0 to 2252-2 can be connected by a common contact (via) 2254.

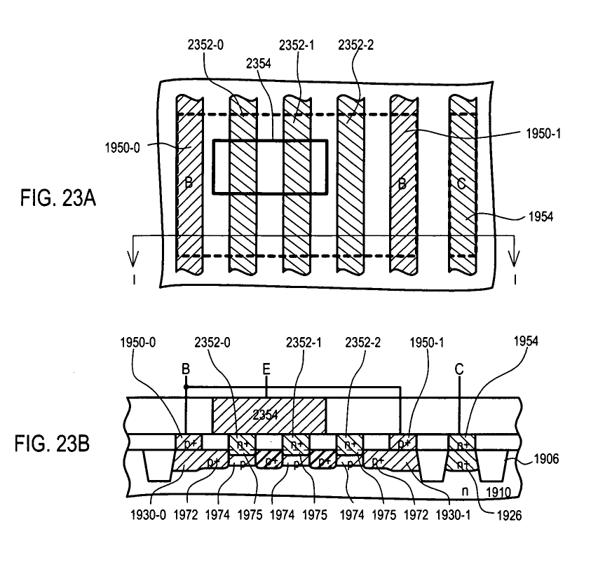

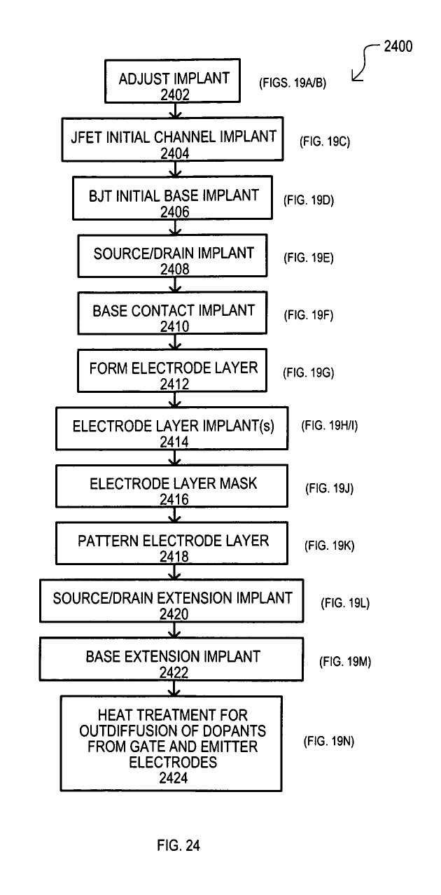

FIGS. 23A and 23B show the same general approach as FIGS. 22A and 22B, but with a different arrangement of emitter electrodes. FIGS. 23A/B show emitter electrodes 2352-0 and 2352-2 conductively connected with contact (via) 2354.

In this way, both JFET and BJT devices can be formed in the same substrate and have the same general structure.

Referring to FIG. 24, a method according to an embodiment is shown in a flow diagram and designated by the general reference character 2400. The flow diagram 2400 follows the same steps shown in FIGS. 19A to 19N, thus numbered block steps reference figures referenced to the right of such blocks.

Reference in the description to “one embodiment” or “an embodiment” means that a particular feature, structure, or characteristic described in connection with the embodiment is included in at least one embodiment of the invention. The appearance of the phrase “in one embodiment” in various places in the specification do not necessarily all refer to the same embodiment. The term “to couple” or “electrically connect” as used herein may include both to directly and to indirectly connect through one or more intervening components.

Further it is understood that the embodiments of the invention may be practiced in the absence of an element or step not specifically disclosed. That is, an inventive feature of the invention may include an elimination of an element.

While various particular embodiments set forth herein have been described in detail, the present invention could be subject to various changes, substitutions, and alterations without departing from the spirit and scope of the invention.

What is claimed is:

1. An integrated circuit device, comprising:
at least one bipolar junction transistor (BJT) that includes
at least a first base electrode comprising a semiconductor material doped to a first conductivity type formed on and in contact with a surface of the semiconductor substrate, the at least first base electrode being separated from an emitter electrode in a direction parallel to the surface of the substrate by a separation space,
a first base region formed in the substrate below the emitter electrode and comprising a first portion of the substrate doped to the first conductivity type, and
a second base region formed in the substrate below the separation space and comprising a second portion of the substrate doped to the first conductivity type and having a different dopant concentration than the first base region.

2. The integrated circuit device of claim 1, wherein:
the emitter electrode comprises the semiconductor material doped to a second conductivity type formed on and in contact with the surface of the semiconductor substrate.

3. The integrated circuit device of claim 2, wherein:
the at least one BJT further includes
an emitter region formed in the substrate between the emitter electrode and the first base region and comprising a third portion of the substrate doped to the second conductivity type.

4. The integrated circuit device of claim 1, wherein:
the at least one BJT further includes
a third base region formed in the substrate below at least a portion of the at least first base electrode and comprising a third portion of the substrate doped to the first conductivity type.

5. The integrated circuit device of claim 1, wherein:
the at least one BJT further includes
a collector region formed in the substrate below at least the first base region and comprising at least a third portion of the substrate doped to the second conductivity type.

6. The integrated circuit device of claim 5, wherein:
the collector region includes at least
a first collector portion comprising the third portion of the substrate, and
a second collector portion formed below the first collector portion, the second collector portion comprising a fourth portion of the substrate doped to the second conductivity type at a higher concentration than the first collector portion.

7. The integrated circuit device of claim 1, further including:
at least one junction field effect transistor (JFET) that includes
at least a drain electrode comprising the semiconductor material doped to one conductivity type formed on and in contact with the surface of the semiconductor substrate, the at least drain electrode being separated from a gate electrode in a direction parallel to the surface of the substrate by a gate separation space,
a channel region formed in the substrate below the gate electrode and comprising a third portion of the substrate doped to the one conductivity type, and
a first drain region formed in the substrate below the gate separation space and comprising a fourth portion of the substrate doped to the one conductivity type and having a different dopant concentration than the channel region.

8. The integrated circuit device of claim 7, wherein:
the at least one JFET further includes
a gate region formed in the substrate between the gate electrode and the channel base region and comprising a fifth portion of the substrate doped to a conductivity type different from the one conductivity type,
a well region formed in the substrate below at least the channel region and comprising a sixth portion of the substrate doped to the same conductivity type as the gate region, and
a well electrode comprising the semiconductor material doped to the same conductivity type as the well region and formed on and in contact with the surface of the semiconductor substrate, and electrically coupled to the well region.

9. The integrated circuit device of claim 7, wherein:
the gate electrode comprises the semiconductor material doped to another conductivity type different from the one conductivity type, the gate electrode being formed on and in contact with the surface of the semiconductor substrate.

10. The integrated circuit device of claim 1, wherein:
the substrate is a semiconductor-on-insulator substrate that includes semiconductor regions formed on an isolation layer, the isolation layer being below the surface of the substrate and extending parallel to the surface of the substrate; and
the at least one BJT is formed in one of the semiconductor regions above a portion of the isolation layer.

11. A method of forming an integrated circuit device having at least a bipolar junction transistor (BJT), comprising the steps of:
a) forming a first BJT base region of a first conductivity type in a semiconductor substrate doped to a second conductivity type;
b) forming an electrode layer comprising a semiconductor material over and in contact with a surface of the substrate, including the BJT base region;
c) patterning the electrode layer to form at least a BJT base electrode separated from a BJT emitter electrode in a direction parallel to the substrate surface by a separation space; and
d) forming a second BJT base region of the first conductivity type in the substrate below the separation space and essentially not below the BJT base electrode, a depth of the second BJT base region with respect to the substrate surface being different than a depth of the first BJT base region.

12. The method of claim 11, wherein:
the step d) includes an ion implantation step that is self-aligned with respect to the BJT emitter electrode and the BJT emitter electrode does not include side wall spacers.

13. The method of claim 11, wherein:
the step b) further includes doping portions of the electrode layer corresponding to the BJT base electrode to the first conductivity type and doping portions of the electrode layer corresponding to the BJT emitter electrode to the second conductivity type.

14. The method of claim 13, further including:
diffusing dopants from the BJT emitter electrode into the substrate to form a BJT emitter region below the BJT emitter electrode, the BJT emitter region comprising a portion of the substrate doped to the second conductivity type.

15. The method of claim 12, wherein:
before step b), forming a third BJT base region of the first conductivity type in the semiconductor substrate; and
the step b) further includes forming the BJT base electrode over and in contact with at least a portion of the third BJT base region.

16. The integrated circuit device of claim 15, wherein:
before step a), forming a BJT collector region of the second conductivity type below the base region, the collector region comprising a buried layer formed in, but not extending to a top surface of the semiconductor substrate; and
the step b) further includes forming a BJT collector electrode over and in contact with the top surface of the substrate.

17. The method of claim 11, wherein:
the step b) further includes forming the electrode layer over and in contact with a channel region of a junction field effect transistor (JFET), the channel region being formed in the substrate and of one conductivity type; and
the step c) further includes patterning the electrode layer to form at least a JFET gate electrode separated from a JFET drain electrode in a direction parallel to the substrate surface by a gate separation space, the JFET gate electrode being formed over at least a portion of the channel region and being doped to a conductivity type different than the one conductivity type.

18. The method of claim 16, further including:
forming a first JFET drain region of the one conductivity type below the gate separation space and essentially not below the JFET gate electrode.

19. The method of claim 16, wherein:
diffusing dopants from the JFET gate electrode into the substrate to form a JFET gate region between the JFET gate electrode and the channel region, the JFET gate region comprising a portion of the substrate doped to the same conductivity type as the gate electrode.

20. The method of claim 16, wherein:
d) forming the first JFET drain region includes an ion implantation step that is self-aligned with respect to the JFET gate electrode and the gate electrode does not include side wall spacers.

21. An integrated circuit device, comprising:
at least one bipolar junction transistor (BJT) comprising
an emitter that includes at least one doped semiconductor emitter electrode formed on and in contact with a surface of a semiconductor substrate, and an emitter region formed by dopants diffusing into the substrate from the emitter electrode,
a base that includes a first base region formed below, and creating a pn junction with, the emitter region, and a second base region formed adjacent to the first base region in a direction parallel to the surface of the semiconductor substrate, and having a different dopant concentration than the first base region, and
a collector that includes at least a portion of the substrate formed below at least the first base region.

22. The integrated circuit device of claim 21, further including:
at least one junction field effect transistor (JFET) comprising
a first gate that includes a doped semiconductor gate electrode formed on and in contact with the surface of the semiconductor substrate, and a first gate region formed by dopants diffusing into the substrate from the gate electrode,
a channel region formed below, and creating a pn junction with, the gate region,
a source region formed adjacent to a first side of the channel region in a direction parallel to the surface of the semiconductor substrate, and a drain region formed adjacent to a second side of the channel region opposite to the first side of the channel region, the source and drain regions having a different dopant concentration than the channel region, and
a second gate that includes at least a portion of the substrate formed below at least the channel region.

23. The integrated circuit of claim 22, wherein:
the at least one doped semiconductor emitter electrode and doped semiconductor gate electrode are formed from a same semiconductor layer.

24. The integrated circuit of claim 23, wherein:
the at least one BJT includes the emitter electrode being formed between a first base electrode portion a second base electrode portion; and
the at least one JFET further includes the gate electrode being formed between a source electrode and a drain electrode in the same manner that the emitter electrode is formed between the first and second base electrode portions; wherein
the first and second base electrode portions, source electrode, and drain electrode are formed from the same semiconductor layer as the emitter and gate electrodes, and the at least BJT differs from the JFET in that the first and second base electrodes are shorted to one another while the source and drain electrodes are not shorted to one another.

25. The integrated circuit of claim 21, wherein:
the emitter includes a plurality of doped semiconductor emitter electrodes, at least a portion of which are conductively connected together by a layer different from that which forms the emitter electrodes.
